(19) United States
(12) Patent Application Publication
(10) Pub. No.: US 2008/0231332 A1
(43) Pub. Date: Sep. 25, 2008

(54) Clock Signal Generation Device, Semiconductor Integrated Circuit, and Data Reproduction Method

(75) Inventors: Kohei Nakata, Nara (JP); Harumitsu Miyashita, Nara (JP)

Correspondence Address: SNELL & WILMER L.L.P. (Matsushita), 600 ANTON BOULEVARD, SUITE 1400, COSTA MESA, CA, 92626, US

(73) Assignee: MATSUSHITA ELECTRIC INDUSTRIAL CO., LTD., Osaka (JP)

(21) Appl. No.: 10/599,237

(22) PCT Filed: Mar. 23, 2005
(86) PCT No.: PCT/JP2005/005288

§ 371 Date: Sep. 22, 2006

(30) Foreign Application Priority Data
Mar. 23, 2004 (JP) 2004-084352
Oct. 5, 2004 (JP) 2004-292214

(51) Int. Cl. H03L 7/06

(52) U.S. Cl. 327/147

(57) ABSTRACT

The present invention improves a lead-in time of the PLL with a phase error detector having an enlarged range of phase error detection and gain control based on the PLL synchronous state. The phase error detection range is enlarged by correcting the phase error detection point in a case where the phase error increases. A locked state of the PLL is determined based on a standard deviation of the smoothed phase error values and the gains are switched between a lead-in transient state and a stationary state. As a result, it is possible to shorten and stabilize the lead-in time of the PLL.

### TECHNICAL FIELD

The present invention relates to a PLL device (clock signal generation device) for generating a timing signal (clock signal) for binarizing the reproduced signal reproduced from a medium on which information is recorded, a semiconductor integrated circuit used therein and a data reproduction method.

### BACKGROUND ART

Conventionally, when information is reproduced from an optical disc on which the information is recorded, a signal reproduced from the disc is input to a PLL (Phase Locked Loop) circuit, a clock signal which is synchronous with the reproduced signal is generated by the PLL circuit, and the reproduced signal is digitalized in synchronization with the clock signal so as to reproduce digital data (see, for example, Reference 1 below).

FIG. 19 is a block diagram showing a configuration of a conventional PLL circuit for generating a clock signal.

An optical head 4102 irradiates an optical disc 4101 with a light beam, detects an amount of the reflected light from the optical disc 4101, and outputs an electric signal. An analog signal processing circuit 4200 extracts a reproduced signal from the electric signal output from the optical head 4102. The analog signal processing circuit 4200 includes: a preamplifier 4201 for amplifying the electric signal; a gain control circuit (AGC) 4202 for controlling the amplitude of the amplified signal to be constant; and an equalizer 4203 for improving a frequency characteristic.

A PLL circuit 4300 generates a clock signal which is synchronous with the reproduced signal. The PLL circuit 4300 includes: an A/D converter 301 for digitalizing the reproduced signal with the clock signal; an offset canceller 4302 for removing a lower frequency component such that a center value of the digital value obtained by digitalizing the reproduced signal becomes zero; a phase error calculator 4303 for calculating a phase error value from the digital value after the offset cancellation; a loop filter 4304 for removing an unnecessary frequency band component from the phase error value; and a clock oscillator 4400 for generating a clock signal having a frequency corresponding to the output value of the loop filter 4304.

The clock oscillator 4400 includes: a D/A converter 4401 for converting the loop filter output value into a voltage signal; a voltage control oscillator (VCO) 4402 for generating a clock signal corresponding to the voltage signal.

FIG. 20 is a timing diagram showing an operation of the phase error calculator 4303.

Portion (A) of FIG. 20 shows an output value of the offset canceller 4302 (that is, a digital value after the offset cancellation). The phase error calculator 4303 detects a zero-cross point from digital values, determines a position of a digital value, whichever is smaller in the absolute value, of two digital value between which the zero-cross point is sandwiched, as a zero-cross detection position (see portion (B) of FIG. 20).

In a case where an inclination of the digital value at the zero-cross detection position is of a rising edge, the digital value is output as it is as the phase error value. In a case where an inclination of the digital value at the zero-cross detection position is of a falling edge, a value obtained by multiplying the digital value with −1 is output as the phase error value (see portion (C) of FIG. 20).

The PLL circuit 4300 operates as a loop controlling the frequency of the clock signal such that the phase error becomes zero based on the phase error value output from the phase error calculator 4303.

The offset canceller 4302 operates based on the phase error value and a duty ratio of 1 and 0, which are values of the binary signal. The offset canceller 4302 controls an offset cancellation level (i.e., a binarization level) such that these values are added and the accumulated value becomes zero (see, for example, Reference 2).

Reference 1: Japanese Laid-open Publication No. 2000-100083

Reference 2: Japanese Laid-open Publication No. 2000-243032

Reference 3: Japanese Laid-open Publication No. 10-107623

Reference 4: Japanese Laid-open Publication No. 2000-285605

Reference 5: Japanese Laid-open Publication No. 2002-334520

Reference 6: Japanese Laid-open Publication No. 2000-343025

Reference 7: Japanese Patent No. 3301691

### DISCLOSURE OF THE INVENTION

However, in a conventional technique, a range where the phase error value can be calculated is limited to only ±½ cycle of the clock signal. The capture range of the PLL circuit is narrow. Thus, in a case where the frequency error between the reproduced signal and the clock signal is increased rapidly, or in a case where the quality of the reproduced signal is degraded due to dust, scratches or finger prints on the optical disc, a state where the reproduced signal and the clock signal are not synchronous with each other may occur. Once the reproduced signal and the clock signal are not synchronous with each other, a problem occurs in that it takes long time until the reproduced signal and the clock signal are synchronous with each other, and there is also a problem that, in the worst case, the reproduced signal and the clock signal are not expected to be synchronous with each other, so that data cannot be reproduced.

Conventionally, in order to determine a synchronous state of the reproduced signal and the clock signal, it is necessary to detect a synchronization code for data reproduction included in the reproduced signal. Accordingly, once the reproduced signal and the clock signal are not synchronous with each other when the quality of the reproduced signal is degraded due to dust, scratches or finger prints on the optical disc, there is problem that it takes long time until the reproduced signal and the clock signal are synchronous with each other, so that the reproduction performance is degraded.

The present invention is intended to solve the problems described above. The purpose of the present invention is to provide a clock signal generation device capable of improving the reproduction performance by immediately performing the lead-in operation of the PLL in a stable manner, even if the reproduced signal and the clock signal are not synchronous with each other.

In a conventional technique, the range where the phase error can be calculated is limited to only ±½ cycle of the clock signal. Accordingly, in a case where the capture range of the PLL is narrow and the frequency of the reproduced signal differs from the frequency of the clock signal, it takes long time to perform the lead-in operation of the PLL. In order to address this problem, a clock signal generation circuit capable of enlarging the capture range of the PLL has been proposed (see, for example, Reference 3 and Reference 4). In the proposed clock signal generation circuit, the frequency error is calculated from an inclination of the phase error value relative to the time axis, and the frequency of the clock signal is controlled based on the calculated frequency error and the phase error.

However, in the conventional technique for enlarging the capture range of the PLL, a capture error state is determined based on a position where an inclination of the phase error value is steep (e.g., an instant state where the phase error is changed by 180 degrees). As a result, if the quality of the reproduced signal is degraded due to dust, scratches or finger prints on the optical disc, or the surface deflection of the optical disc, erroneous detection or non-detection is caused. Accordingly, there is a problem that the lead-in time in the PLL is not stable and it takes a long time to reproduce data.

In a conventional technique, in order to improve a precision in detecting the capture error state, a plurality of phase error values are held and a displacement of the phase error curve is detected from the held phase error values. However, it is necessary to hold many phase error values in order to obtain a sufficient detection precision in a data interval without using known specific patterns. There is a problem that the scale of the circuit becomes very large.

In a conventional offset canceller, a binary level is easily deflected due to influence of a short mark/space portion where the amplitude of the reproduced signal is easily reduced. As a result, when the quality of the reproduced signal is bad, the binary level may be controlled into a wrong level. Accordingly, there is a problem that the calculation of the phase error value based on a zero-cross point is not normally performed, so that the lead-in operation cannot be performed in the PLL.

The present invention is intended to solve the problems described above. The purpose of the present invention is to provide a clock signal generation device capable of improving the reproduction performance by immediately performing the lead-in operation in a stable manner, even if the reproduced signal and the clock signal are not synchronous with each other, and to implement such a clock signal generation device having a simplified structure.

The clock signal generation device of the present invention is a clock signal generation device for generating a clock signal which is synchronous with a reproduced signal from an optical disc on which information is recorded, including: an A/D converting means for sampling the reproduced signal in response to the clock signal and for converting the sampled reproduced signal into a digital value so as to generate a plurality of digital values sequentially in time; a phase error calculating means for calculating a phase error value indicating a phase error between the reproduced signal and the clock signal based on each of the plurality of digital values; a loop filter means for outputting a control signal controlling a frequency of the clock signal based on the phase error value; a clock oscillating means for generating a signal having a frequency corresponding to the control signal as the clock signal; and a phase error range determining means for determining whether or not the phase error is within a predetermined range based on the phase error value, wherein the phase error calculating means detects zero-cross points of the plurality of digital values, calculates the phase error value based on a digital value which is closer to the zero level among two digital values between the zero-cross points when it is determined that the phase error is within the predetermined range by the phase error range determining means, and calculates the phase error value based on a digital value which is further from the zero level among the two digital values when it is determined that the phase error is not within the predetermined range by the phase error range determining means.

The phase error range determining means may include a low-pass filter means for smoothing the phase error value and the phase error range determining means determines whether or not the phase error is within the predetermined range based on a result of comparison between an output value of the low-pass filter means and a predetermined threshold value.

The phase error range determining means may control the loop filter means such that a gain of the loop filter means becomes higher when it is determined that the phase error is not within the predetermined range.

The clock signal generation device may further include: a synchronization determining means for determining whether or not the reproduced signal and the clock signal are synchronous with each other based on the amplitude of the control signal, and wherein: the synchronization determining means makes the determination by the phase error range determining means valid, when it is determined that that the reproduced signal and the clock signal are not synchronous with each other, and the synchronization determining means makes the determination by the phase error range determining means invalid, when it is determined that the reproduced signal and the clock signal are synchronous with each other.

The clock signal generation device may further include: an offset canceling means for detecting a level at which the digital value is binarized and for canceling an offset component of the digital value based on the level, wherein the phase error calculating means calculates the phase error value based on the digital value where the offset component of the digital value has been cancelled by the offset canceling means.

The clock signal generation device may further include: a synchronization determining means for determining whether or not the reproduced signal and the clock signal are in synchronous with each other based on the amplitude of the control signal, and wherein: the synchronization determining means controls the offset canceling means such that a gain of the offset canceling means becomes higher, when it is determined that the reproduced signal and the clock signal are not synchronous with each other, and the synchronization determining means controls the offset canceling means such that a gain of the offset canceling means becomes lower, when it is determined that the reproduced signal and the clock signal are synchronous with each other.

The clock signal generation device may further include: an accumulation means for accumulating the digital values over each of predetermined intervals; an averaging means for averaging the accumulated values by the accumulation means; and an error detecting means for detecting an error when a difference between the accumulated value by the accumulation means and the average value by the averaging means is larger than a predetermined threshold value, wherein the synchronization determining means determines that the signals are not synchronous with each other when an error is detected by the error detecting means.

The semiconductor integrated circuit according to the present invention is a semiconductor integrated circuit used in a clock signal generation device for generating a clock signal which is synchronous with a reproduced signal from an optical disc on which information is recorded, wherein the clock signal generation device includes an A/D converting means for sampling the reproduced signal in response to the clock signal and for converting the sampled reproduced signal into a digital value so as to generate a plurality of digital values sequentially in time; and a clock oscillating means for generating the clock signal, the semiconductor integrated circuit including: a phase error calculating means for calculating a phase error value indicating a phase error between the reproduced signal and the clock signal based on each of the plurality of digital values; a loop filter means for outputting a control signal controlling a frequency of the clock signal based on the phase error value; and a phase error range determining means for determining whether or not the phase error is within a predetermined range based on the phase error value, wherein: the phase error calculating means detects zero-cross points of the plurality of digital values, calculates the phase error value based on a digital value which is closer to the zero level among two digital values between the zero-cross points when it is determined that the phase error is within the predetermined range by the phase error range determining means, and calculates the phase error value based on a digital value which is further from the zero level among the two digital values when it is determined that the phase error is not within the predetermined range by the phase error range determining means, and the clock oscillating means generates a signal having a frequency corresponding to the control signal as the clock signal.

The data reproduction method according to the present invention is a data reproduction method for generating a clock signal which is synchronous with a reproduced signal from an optical disc on which information is recorded and for outputting reproduced data obtained by digitizing the reproduced signal in synchronization with the clock signal, the data reproduction method including the steps of: (a) sampling the reproduced signal in response to the clock signal and converting the sampled reproduced signal into a digital value so as to generate plurality of digital values in the order of time sequence; (b) calculating a phase error value indicating a phase error between the reproduced signal and the clock signal based on each of the plurality of digital values; (c) outputting a control signal controlling a frequency of the clock signal based on the phase error value; (d) generating a signal having a frequency corresponding to the control signal as the clock signal; and (e) determining whether or not the phase error is within a predetermined range based on the phase error value, wherein the step (b) includes the steps of: detecting zero-cross points of the plurality of digital values; calculating the phase error value based on a digital value which is closer to the zero level among two digital values between the zero-cross points when it is determined that the phase error is within the predetermined range in the phase error range determining step; and calculating the phase error value based on a digital value which is further from the zero level among the two digital values when it is determined that the phase error is not within the predetermined range in the phase error range determining step.

The clock signal generation device according to the present invention is a clock signal generation device for generating a clock signal which is synchronous with a reproduced signal from a disc on which information is recorded, including: an A/D converting means for sampling the reproduced signal in response to the clock signal and for converting the sampled reproduced signal into a digital value so as to generate a plurality of digital values in the order of time sequence; a first phase error calculating means for calculating a first phase error value indicating a phase error between the reproduced signal and the clock signal based on each of the plurality of digital values; a first displacement distribution detecting means for detecting a distribution of displacements of the first phase error values; a loop filter means for generating a control signal controlling a frequency of the clock signal based on the first phase error values and a detection result of the distribution of displacements of the first phase error values; and a clock oscillating means for generating a signal having a frequency corresponding to the control signal as the clock signal, wherein the loop filter means generates the control signal such that a deviation of the distribution of displacements of the first phase error values becomes smaller.

The clock signal generation device may further include: a synchronization determining means for determining whether or not the reproduced signal and the clock signal are synchronous with each other based on the amplitude of the control signal, wherein: the synchronization determining means makes the detection by the first displacement distribution detecting means valid, when it is determined that the reproduced signal and the clock signal are not synchronous with each other, and the synchronization determining means makes the detection by the first displacement distribution detecting means invalid, when it is determined that the reproduced signal and the clock signal are synchronous with each other.

The clock signal generation device may further include: an accumulation means for accumulating the digital values over each of predetermined intervals; an averaging means for averaging the accumulated values by the accumulation means; and an error detecting means for detecting an error when a difference between the accumulated value by the accumulation means and the average value by the averaging means is larger than a predetermined threshold value, wherein the synchronization determining means determines that the signals are not synchronous with each other when an error is detected by the error detecting means.

The loop filter means may generate the control signal such that the deviation of the distribution of displacements of the first phase error values becomes smaller.

The loop filter means may use only values having polarity where the deviation of the distribution of displacements of the first phase error values becomes smaller, when the deviation of the distribution is large.

The displacement distribution detecting means may detect the distribution by accumulating signs of the displacements.

The displacement distribution detecting means may accumulate the signs of the displacements only when the absolute value of the displacement is larger than a predetermined value.

The displacement distribution detecting means may increase or decrease accumulated values of the signs of the displacements such that the absolute value of the accumulated values becomes smaller, when the absolute value of the displacement is smaller than a predetermined value.

The clock signal generation device may further include: a higher frequency band emphasizing filter means for emphasizing a higher frequency band component of a digital value; a second phase error calculating means for calculating a second phase error value indicating a phase error between the reproduced signal and the clock signal based on an output signal of the higher frequency band emphasizing filer means; and a second displacement distribution detecting means for detecting a distribution of displacements of the second phase error values, wherein the loop filter means generates the control signal such that a deviation of the distribution of displacements of the second phase error values becomes smaller.

The clock signal generation device may further include: an offset canceling means for detecting a level at which the digital value is binarized and for canceling an offset component of the digital value based on the level, wherein: the first phase error calculating means calculates the first phase error value based on the digital value where the offset component of the digital value has been cancelled by the offset canceling means, and the high frequency band emphasizing filter means is included in the offset canceling means.

The clock signal generation device may further include: a synchronization determining means for determining whether or not the reproduced signal and the clock signal are synchronous with each other based on the amplitude of the control signal, wherein: the synchronization means controls the offset canceling means such that a gain of the offset canceling means becomes higher, when it is determined that the reproduced signal and the clock signal are not synchronous with each other, and the synchronization means controls the offset canceling means such that a gain of the offset canceling means becomes lower, when it is determined that the reproduced signal and the clock signal are synchronous with each other.

The semiconductor integrated circuit according to the present invention is a semiconductor integrated circuit used in a clock signal generation device for generating a clock signal which is synchronous with a reproduced signal from an optical disc on which information is recorded, wherein the clock signal generation device includes an A/D converting means for sampling a reproduced signal in response to a clock signal and for convert the sampled reproduced signal into a digital signal so as to generate a plurality of digital values sequentially in time; and a clock oscillating means for generating the clock signal, the semiconductor integrated circuit including: a first phase error calculating means for calculating a first phase error value indicating a phase error between the reproduced signal and the clock signal based on each of the plurality of digital values; a first displacement distribution detecting means for detecting a distribution of displacements of the first phase error values; and a loop filter means for generating a control signal controlling a frequency of the clock signal based on the first phase error values and a detection result of the distribution of displacements of the first phase error values; wherein: the loop filter means generates the control signal such that a deviation of the distribution of displacements of the first error values becomes smaller, and the clock oscillating means generates a signal having a frequency corresponding to the control signal as the clock signal.

The data reproduction method according to the present invention is a data reproduction method for generating a clock signal which is synchronous with a reproduced signal from an optical disc on which information is recorded and for outputting reproduced data obtained by digitizing the reproduced signal in synchronization with the clock signal, the data reproduction method including the steps of: (a) sampling the reproduced signal in response to the clock signal and converting the sampled reproduced signal into a digital value so as to generate a plurality of digital values in the order of time sequence; (b) calculating a first phase error value indicating a phase error between the reproduced signal and the clock signal based on each of the plurality of digital values; (c) detecting a distribution of displacements of the first phase error values; (d) generating a control signal controlling a frequency of the clock signal based on the first phase error values and a detection result of the distribution of displacements of the first phase error values; and (e) generating a signal having a frequency corresponding to the control signal as the clock signal, wherein the step (d) includes the step of generating the control signal such that a deviation of the distribution of displacements of the first phase error values becomes smaller.

According to the present invention described above, by calculating the phase error value based on the determination result on the range of the phase errors, it is possible to enlarge the range where the phase error value can be calculated up to +1 cycle of the clock signal.

By immediately determining a phase synchronization state of the reproduced signal and the clock signal based on the control signal output from the loop filter means, and by properly controlling the clock signal generation device, it is possible to generate a stable clock signal.

According to a clock signal generation device of the present invention, it is possible to enlarge a capture range by correcting a range where the phase error value can be calculated. As a result, it is possible to perform the resynchronization, even if the reproduced signal and the clock signal are not synchronous with each other due to the rapid change of the reproduced signal.

The gain of the loop filter means and the gain of the offset canceling means and phase error range determining means are controlled in accordance with the determination result on the range of the phase error values and the determination result on the synchronization state. In a case where the reproduced signal and the clock signal are not synchronous with each other, the gains are set to be high and a range where the phase error values can be calculated is enlarged. As a result, it is possible to quickly perform the lead-in operation into a synchronous state. In a case where the reproduced signal and the clock signal are synchronous with each other, the gains are set to be low and the range where phase error values can be calculated is not corrected. As a result, it is possible to generate a stable clock signal.

According to another clock signal generation device of the present invention, a distribution of displacements of the phase error values is obtained and a deviation of the distribution is detected. When the detected deviation is large, a control signal controlling the frequency of the clock signal is generated based on the phase error values such that the deviation of the distribution should be eliminated. As a result, it is possible to exactly detect a state where the PPL cannot capture the frequency error between the reproduced signal and the clock signal, even if the quality of the reproduced signal is bad. By controlling the frequency of the clock signal such that the frequency error is within the capture range according to the detection result, it is possible to generate a stable clock signal.

According to one embodiment of the present invention, a distribution of displacements of the phase error values is obtained with an accumulated value obtained by accumulating signs of the displacements of the phase error values. As a result, it is not necessary to hold many phase error values, and it is possible to realize a high precision detection using a small scale circuit.

According to one embodiment of the present invention, the amplitude of a short mark/space portion is amplified by the higher frequency band emphasizing means. As a result, it is possible to improve a precision in detecting a binary level and to stabilize the lead-in operation of the PLL.

### BRIEF DESCRIPTION OF THE DRAWINGS

FIG. 1 is a block diagram showing a configuration of a PLL circuit in a first embodiment of the present invention.

FIG. 2 is a timing diagram showing an operation of the phase error calculation in the first embodiment of the present invention.

FIG. 3 is a block diagram showing a configuration of a phase error range determining circuit in the first embodiment of the present invention.

FIG. 4 is a timing diagram showing an operation of the phase error range determination in the first embodiment of the present invention.

FIG. 5 is a block diagram showing a configuration of a synchronization determining circuit in the first embodiment of the present invention.

FIG. 6 is a diagram showing state transitions of a state machine in the first embodiment of the present invention.

FIG. 7 is a timing diagram showing an operation of the amplitude error detection in the first embodiment of the present invention.

FIG. 8 is a timing diagram showing an operation of the synchronous state determination in the first embodiment of the present invention.

FIG. 9 is a block diagram showing a configuration of a clock signal generation circuit in a second embodiment of the present invention.

FIG. 10 is a block diagram showing a configuration of a displacement distribution detector in the second embodiment of the present invention.

FIG. 11 is a timing diagram showing an operation of the displacement distribution detector in the second embodiment of the present invention.

FIG. 12 is a timing diagram showing an operation of the displacement distribution detector in the second embodiment of the present invention.

FIG. 13 is a timing diagram showing an operation of the displacement distribution detector in the second embodiment of the present invention.

FIG. 14 is a block diagram showing a configuration of a loop filter in the second embodiment of the present invention.

FIG. 15 is a timing diagram showing an operation of the displacement distribution detector and the loop filter in the second embodiment of the present invention.

FIG. 16 is a block diagram showing a configuration of a clock signal generation circuit in a third embodiment of the present invention.

FIG. 17 is a block diagram showing a configuration of a higher frequency band emphasizing filter in the third embodiment of the present invention.

FIG. 18 is a block diagram showing a configuration of a disc device in a fourth embodiment of the present invention.

FIG. 19 is a block diagram showing a configuration of a conventional PLL circuit.

FIG. 20 is a timing diagram showing an operation of the phase error calculation of the conventional PLL circuit.

### BEST MODE FOR CARRYING OUT THE INVENTION

Hereinafter, embodiments of a PLL device (a clock signal generation device) according to the present invention will be described with reference to the drawings.

### First Embodiment

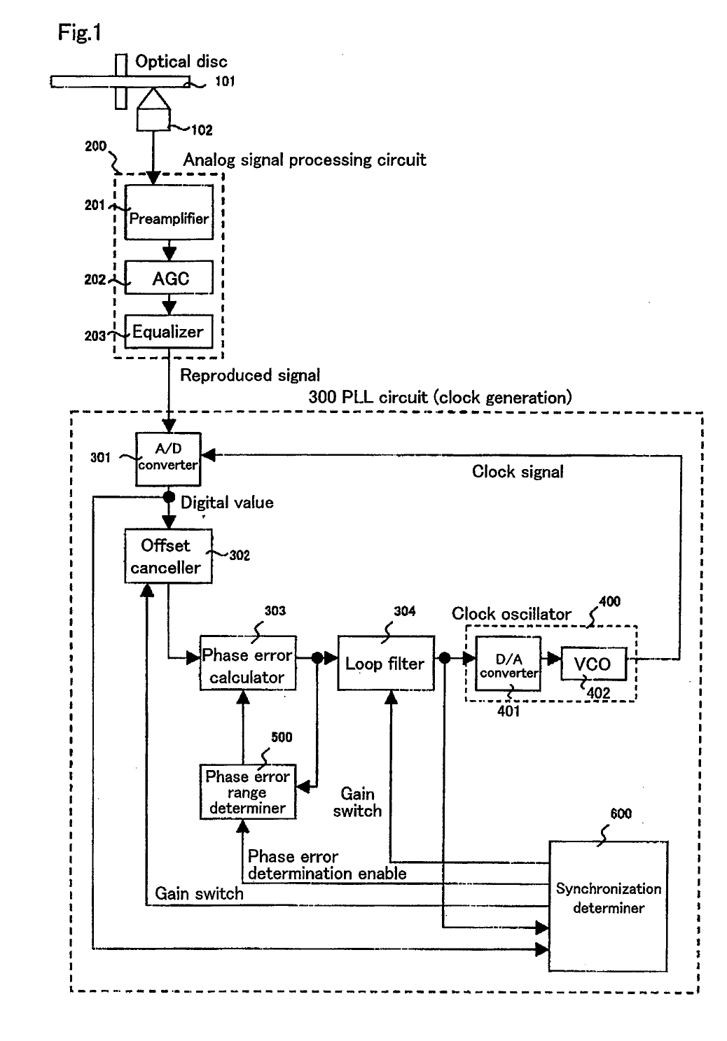

FIG. 1 is a block diagram showing a configuration of a PLL circuit in a first embodiment of the present invention.

An optical head 102 irradiates an optical disc 101 with a light beam, detects an amount of the reflected light from the optical disc 101 and outputs an electric signal. An analog signal processing circuit 200 extracts a reproduced signal from the electric signal output from the optical head 102. The analog signal processing circuit 200 includes a preamplifier 201 for amplifying the electric signal, a gain control circuit (AGC) 202 for controlling the amplitude of the amplified signal to be constant and an equalizer 203 improving a frequency characteristic.

Next, a configuration of a PLL circuit 300 will be described.

The PLL circuit 300 generates a clock signal which is synchronous with a reproduced signal. The clock signal generation circuit 300 includes: an A/D converter 301 for digitalizing the reproduced signal with the clock signal; an offset canceller 302 for removing a lower frequency component such that the center value of the digital value obtained by digitizing the reproduced signal is to be zero; a phase error calculator 303 for calculating a phase error between the digital value output from the offset canceller 302 and the clock signal; a phase error range determiner 500 for controlling the correction of a calculation range for a phase error value by the phase error calculator 303; a loop filter 304 for removing an unnecessary frequency band component from a phase error value; a clock oscillator 400 for generating a clock signal having a frequency corresponding to an output value of the loop filter 304; and a synchronization determiner 600 for determining a phase synchronization state between the reproduced signal and the clock signal based on an output value of the loop filter.

The digital value obtained by digitalizing the reproduced signal by the A/D converter 301 includes an unnecessary lower frequency band component which remains without being removed in the analog signal processing circuit 200. The offset canceller 302 extracts the lower frequency band component and subtracts the extracted offset value from the digital value so as to remove the lower frequency band component. This makes it possible to perform a stable clock generating operation, even if the reproduced signal is swayed by a low frequency due to dust or finger prints attached on an information recording surface of the optical disc 101.

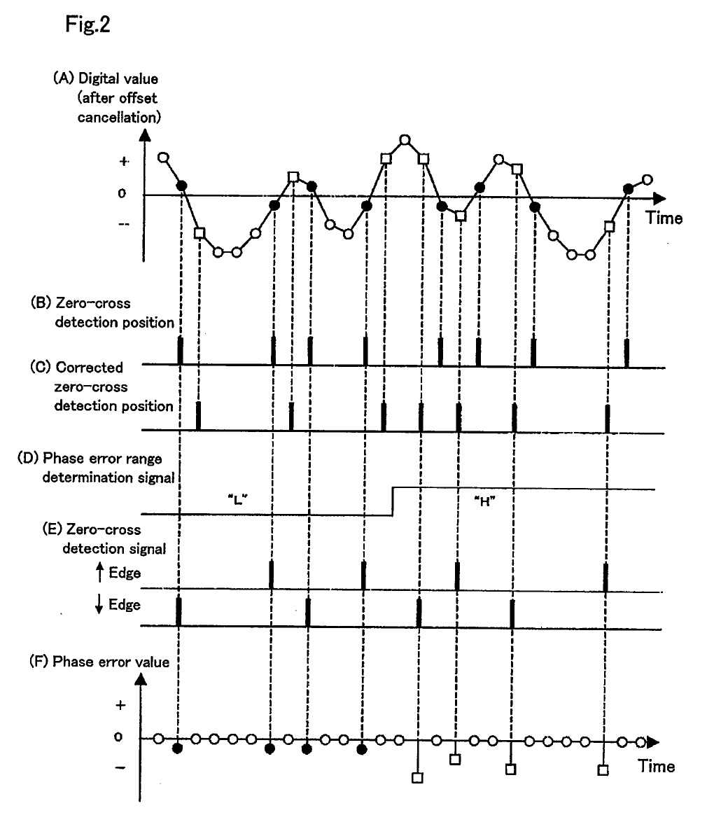

The phase error calculator 303 calculates a phase error value based on the digital value after the offset cancellation. FIG. 2 is a timing diagram showing an operation of the phase error calculator 303. Portion (A) of FIG. 2 shows digital values after the offset cancellation in the order of time sequence. Among the digital values, two digital values are detected such that one digital value exists before a zero-cross point and the other digital value exists after the zero-cross point, and a position of one of the two digital values, which has an absolute value smaller than the other digital value, is determined as a zero-cross detection position (see portion (B) of FIG. 2). A position of the other digital value of the two digital values is determined as a corrected zero-cross detection position (see portion (C) of FIG. 2). Among the zero-cross detection position and the corrected zero-cross detection position, the zero-cross detection position is selected when a determination signal from the phase error range determiner 500 takes “L” level indicating “without correction”, whereas the corrected zero-cross detection position is selected when a determination signal from the phase error range determiner 500 takes “H” level indicating “with correction” (see portions (D) and (E) of FIG. 2). When an inclination of the digital value at the selected position is of a rising edge, the digital value itself is output as the phase error value. When an inclination of the digital value at the selected position is of a falling edge, a value obtained by multiplying the digital value with −1 is output as the phase error value.

An unnecessary frequency band component is removed from the phase error value by the loop filter 304. The output value of the loop filter 304 is input to the clock oscillator 400. The clock oscillator 400 includes: a D/A converter 401 for converting the output value of the loop filter 304 into a voltage signal; and a voltage control oscillator (VCO) 402. The frequency of the clock signal generated by the VOC 402 becomes higher as the output value of the loop filter 304 increases and the output voltage of the D/A converter 401 becomes higher. The frequency of the clock signal generated by the VCO 402 becomes lower as the output value of the loop filter 304 decreases and the output voltage of the D/A converter 401 becomes lower. Accordingly, the PLL circuit 300 operates to increase the frequency of the clock signal when the phase error value calculated by the phase error calculator 303 is a positive value, and it operates to decrease the frequency of the clock signal when the phase error value calculated by the phase error calculator 303 is a negative value.

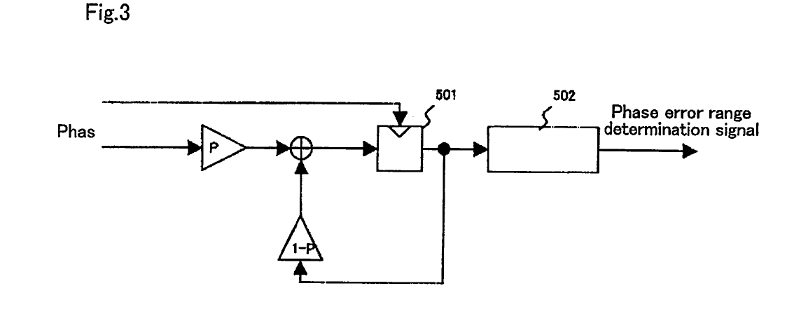

FIG. 3 is a block diagram showing a configuration of the phase error range determiner 500. The phase error value calculated by the phase error calculator 303 is multiplied by P. The P-multiplied value is delayed by a delay unit 501. The value output from the delay unit 501 is multiplied by (1-P). The (1-P)-multiplied value is added to the P-multiplied value. The added value is again input to the delay unit 501. The value of P may be, for example, ½. The loop circuit including the delay unit 501 operates each time the phase error value is calculated by the phase error calculator 303. Thus, the absolute value of the output value of the delay unit 501 is increased in a case where the phase error value is increased or decreased continuously. A comparator 502 outputs a phase error range determination signal as being determined that the correction of the phase error calculation range is required, in a case where the output value of the delay unit 501 is greater than a predetermined threshold value on the + side, or in a case where the output value of the delay unit 501 is smaller than a predetermined threshold value on the − side.

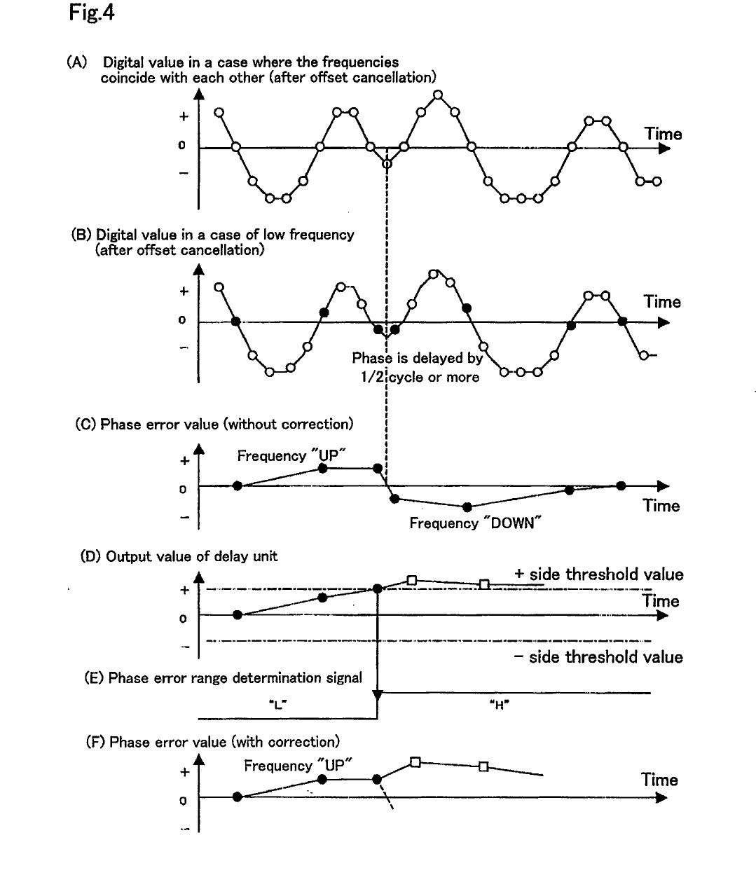

FIG. 4 is a timing diagram showing an operation of the phase error range determiner 500.

Portion (A) of FIG. 4 shows digital values in a case where the reproduced signal and the clock signal are synchronous with each other, where the digital values at zero-cross detection positions are zero.

Portion (B) of FIG. 4 shows digital values in a case where the frequency of the clock signal is lower than the frequency of the reproduced signal. Since the frequency of the clock signal is lower, the phase of the clock signal is delayed against the phase of the reproduced signal by ½ cycle or more of the clock signal for every several cycles.

Portion (C) of FIG. 4 shows a phase error value in this situation. In a case where no correction is applied to a phase error calculation range, the phase error calculation range is limited to only ±½ cycles. As a result, the phase error value takes a value indicating the increase of the frequency of the clock signal (i.e., frequency “UP”) as far as the delay of the phase of the clock signal is within ½ cycle. However, once the delay of the phase of the clock signal exceeds ½ cycle, the phase error value takes a value indicating the decrease of the frequency of the clock signal (i.e., frequency “DOWN”). This makes it impossible to generate a synchronized clock signal. Portion (D) of FIG. 4 shows output values of the delay unit 501 in the phase error range determiner 500 in this situation.

In a case where the frequency of the clock signal is lower, the absolute value of the output value of the delay unit 501 is increased on the positive side, and it exceeds a predetermined threshold value on the + side when the phase of the clock signal is delayed from the phase of the reproduced signal by ½ cycle of the clock signal. As a result, it is determined that the correction of the phase error range is required and the level of the phase error range determination signal becomes “H” level (see portion (E) of FIG. 4). The phase error calculator 303 selects a corrected zero-cross detection position based on the phase error range determination signal. Thus, a range where the phase error can be calculated becomes a range from +½ cycle to +1 cycle. In this case, as far as the delay of the phase does not exceed +1 cycle, it is possible to continuously output the phase error value indicating frequency “UP”. As a result, it is possible to generate a stably synchronized clock signal.

In a case where the frequency of the clock signal is higher, the absolute value of the output value of the delay unit 501 is increased on the negative side, and it exceeds a predetermined threshold value on the −side when the phase of the clock signal is advanced from the phase of the reproduced signal by ½ cycle of the clock signal. As a result, the level of the phase error range determination signal becomes “H” level. The phase error calculator 303 selects a corrected zero-cross detection position based on the phase error range determination signal. Thus, a range where the phase error can be calculated becomes a range from −½ cycle to −1 cycle. In this case, as far as the delay of the phase does not exceed −1 cycle, it is possible to continuously output the phase error value indicating frequency “DOWN”.

Herein, the threshold value on the + side and the threshold value on the − side can be determined to be a value corresponding to the amplitude of the reproduced signal which is input to the A/D converter 301. This is because the amplitude of the reproduced signal which is input to the A/D converter 301 is controlled to be constant by the gain control circuit (AGC) 202 in the analog signal processing circuit 200.

Next, an operation of a synchronization determiner 600 will be described.

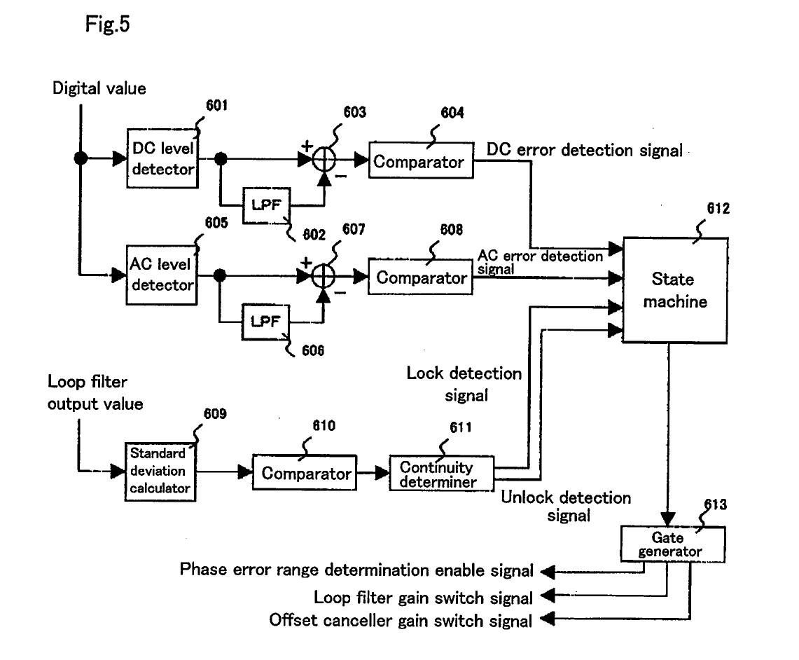

FIG. 5 is a block diagram showing a configuration of the synchronization determiner 600.

The synchronization determiner 600 includes: a DC level detector 601 for detecting a DC level of the digital value output from the A/D converter 301; a low-pass filter (LPF) 602 for smoothing a change in the DC level detection value; a subtracter 603 for calculating a difference between the DC level detection value and the LPF output value; a comparator 604 for comparing the difference value with a predetermined DC error detection threshold value; an AC level detector 605 for detecting an AC level of the digital value output from the A/D converter 301; a low-pass filter (LPF) 606 for smoothing a change in the AC level detection value; a subtracter 607 for calculating a difference between the AC level detection value and the LPF output value; a comparator 608 for comparing the difference value with a predetermined AC error detection threshold value; a standard deviation calculator 609 for calculating a standard deviation of the output value of the loop filter 304; a comparator 610 for comparing the standard deviation with a predetermined standard deviation threshold value; a continuity determiner 611 for determining the continuity of the comparison results; a state machine 612 which operates based on the results of the detection; and a gate generator 613 for controlling the operation of the PLL circuit 300 in accordance with the states.

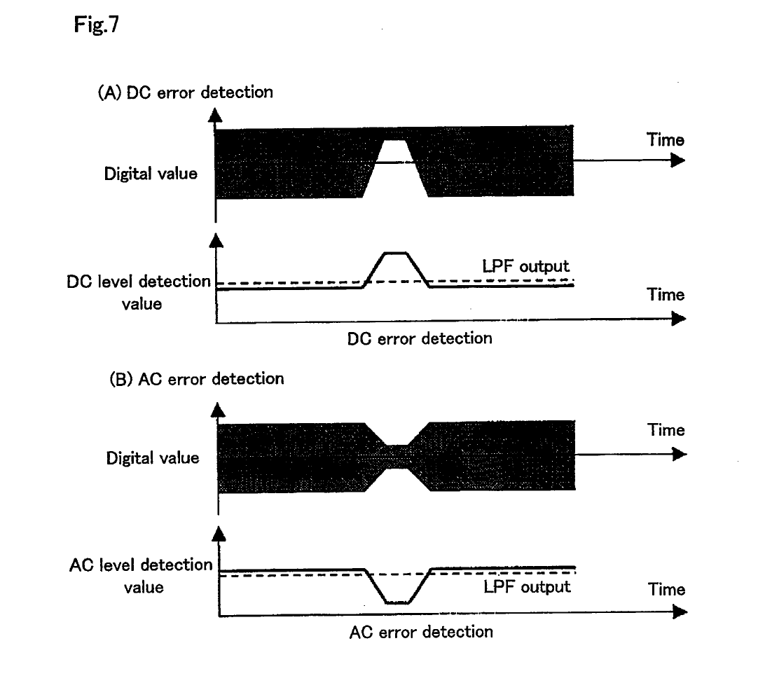

Portion (A) of FIG. 7 is a timing diagram showing an operation of detecting a DC variation of the digital value. The DC level detector 601 obtains an accumulated value of the digital values output from the A/D converter 301 over each of predetermined intervals. Each predetermined interval may be designed such that the length of each predetermined interval is sufficiently shorter than a cycle of a DC variation component to be detected and such that each predetermined interval is longer than a interval where a ratio of information bit “1” to information bit “0” in the digital value is almost 1:1. The average value of the DC level detection values is obtained by smoothing the DC level detection values using the LPF 602. The frequency characteristic of the LPF 602 may be designed such that the DC variation component to be detected is removed. A difference between the DC level detection value and the average value of the DC level detection values is calculated in the subtracter 603. In a case where a DC variation occurs, the absolute value of the difference value is increased. If the absolute value of the difference value exceeds a DC error detection threshold value, the comparator 604 detects a DC error.

Portion (B) of FIG. 7 is a timing diagram showing an operation of detecting an AC variation of the digital value. The AC level detector 605 obtains an accumulated value of the absolute values of the digital values output from the A/D converter 301 over each of predetermined intervals. Each predetermined interval may be designed such that the length of each predetermined interval is sufficiently shorter than a cycle of an AC variation component to be detected. The average value of the AC level detection values is obtained by smoothing the AC level detection values using the LPF 606. The frequency characteristic of the LPE 606 may be designed such that the AC variation component to be detected is removed. A difference between the AC level detection value and the average value of the AC level detection values is calculated in the subtracter 607. In a case where an AC variation occurs, the absolute value of the difference value is increased. If the absolute value of the difference value exceeds an AC error detection threshold value, the comparator 608 detects an AC error.

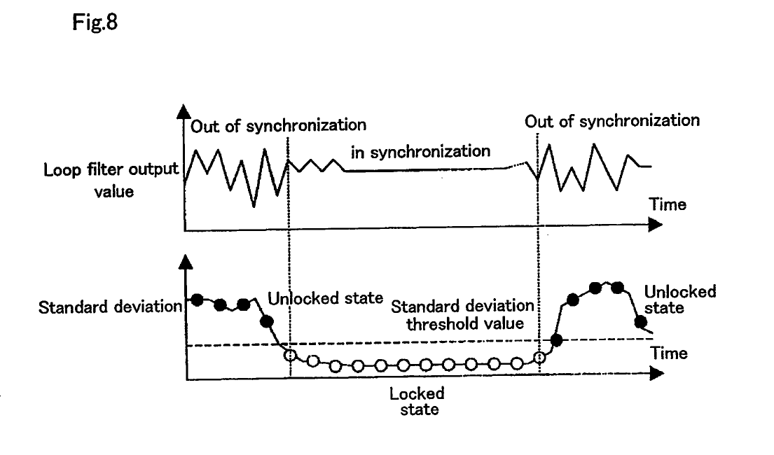

FIG. 8 is a timing diagram showing a change of the output values of the loop filter 304 according to a synchronous state between the produced signal and the clock signal. The standard deviation calculator 609 calculates a standard deviation of the output values of the loop filter 304 over each of predetermined intervals.

The standard deviation becomes larger when the reproduced signal and the clock signal are not synchronous with each other, while the standard deviation becomes smaller when the reproduced signal and the clock signal are synchronous with each other. A synchronous state is determined for each of the predetermined intervals by comparing the change in the standard deviation value with a predetermined standard deviation threshold value in the comparator 610.

If the continuity determiner 611 determines successively by a predetermined number of times that the determination result of the synchronous state is a synchronization “OK” over the respective intervals, the continuity determiner 611 outputs a lock detection signal indicating that the synchronization of the reproduced signal with the clock signal is locked.

On the other hand, if the continuity determiner 611 determines successively by a predetermined number of times that the determination result of the synchronous state is a synchronization “NG” over the respective intervals, the continuity determiner 611 outputs an unlock detection signal indicating that the synchronization of the reproduced signal with the clock signal is unlocked.

Thus, it is possible to exactly determine the synchronous state.

The state machine 612 makes the states to transit based on the DC error detection signal, the AC error detection signal, the lock detection signal and the unlock detection signal. The gate generator 613 outputs a phase error range determination enable signal controlling the operation of the phase error range determiner 500, a loop filter gain switch signal controlling a gain of the loop filter 304 and an offset canceller gain switch signal controlling a gain of the offset canceller 302, based on the states of the state machine 612.

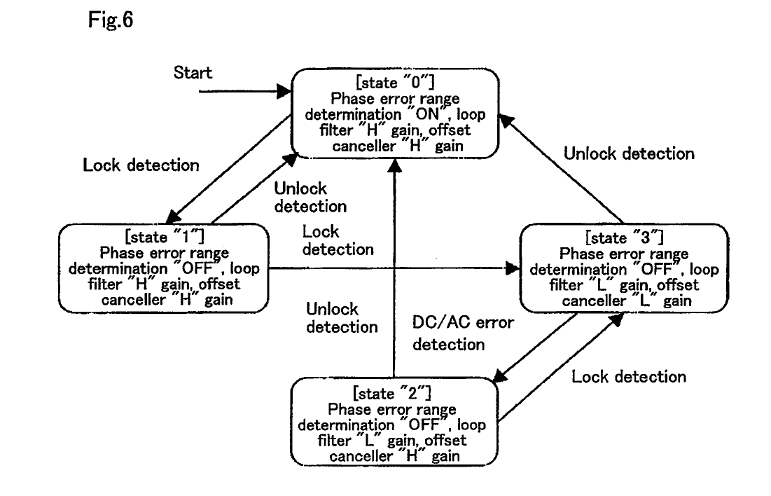

FIG. 6 is a diagram showing the transition of the states in the state machine 612 and the operations of the gate generator 613 in the respective states.

When the operation of the PLL circuit 300 is started, the operation of the state machine is started from state “0”. In state “0”, an error in frequency between the reproduced signal and the clock signal is large. Accordingly, in state “0”, the phase error range determiner 500 is activated in order to stabilize a lead-in operation, a gain of the loop filter 304 is set to be high in order to shorten a lead-in time and a gain of the offset canceller 302 is set to be high in order to control the center of the digital value to be zero immediately.

When the lock detection signal is output, the state transits to state “1”. In state “1”, an error in frequency between the reproduced signal and the clock signal becomes sufficiently small. Accordingly, in state “1”, the phase error range determination is not required, and the operation of the phase error range determiner 500 is stopped in order to prevent the PLL circuit 300 from being destabilized due to a malfunction of phase error range determination caused by the quality reduction of the reproduced signal. In state “1”, the phase control and the offset cancel control of the digital value still do not reach sufficient leading-in. Accordingly, in state “1”, both of the gains are maintained high.

In state “1”, when the lock detection signal is output, the state transits to state “3”. Then, when the unlock detection signal is output, the state transits to state “0” again.

State “3” is a state where it is determined that the reproduced signal and the clock signal are completely synchronous with each other. In state “3”, in order to stabilize the operation of the entire PLL circuit 300, the operation of the phase error range determiner 500 is maintained to be stopped, a gain of the loop filter 304 is set to be low and a gain of the offset canceller 302 is set to be low.

In state “3”, when the unlock is detected, the state transits to state “0” and when the DC error is detected or when the AC error is detected, the state transits to state “2”.

In state “2”, there is a possibility that the control of the offset canceller 302 is destabilized under an influence of the DC variation or the AC variation of the digital value, and there is a possibility that an exact phase error value cannot be calculated by the phase error calculator 303. Accordingly, in state “2”, only the gain of the offset canceller 302 is set to be high in order to immediately lead-in again so that the center of the digital value takes zero.

In state “2”, when the lock is detected, the state transits to state “3” again. In state “3”, when leading-in cannot be stably achieved and unlock is detected, the state transits to state “0”.

According to the present invention, as described above, by the phase error range determination and the calculation of the phase error according to the phase error range determination, it is possible to extend a range where the phase error can be calculated from a range of ±½ cycle of the clock signal to a range of ±1 cycle of the clock signal. Even if an error in frequency between the reproduced signal and the clock signal is large, it is possible to exactly calculate the phase error and to stably generate a clock signal which is synchronous with the reproduced signal.

By determining the synchronous state of the reproduced signal and the clock signal based on the standard deviation of the output value of the loop filter 304, and by controlling the operation of the phase error range determiner 500 and the operation of the loop filter 304 in accordance with the determination result of the synchronous state, it is possible to stabilize a lead-in operation from the start operation of the PLL circuit 300 to a lock state and to shorten the lead-in time.

By detecting errors in the DC variation and the AC variation of the reproduced signal from the digital value using the A/D converter 301 and by controlling the operation of the offset canceller 302 in accordance with the detection result of the errors, it is possible to immediately return to a reproducible state even if a reproduction operation is destabilized under influences of scratches, dust and finger prints on an information recording surface of the optical disc 101, and to improve the reproduction performance.

In the present embodiment, a configuration for performing an offset cancellation after the A/D conversion of the reproduced signal is described above. However, it may be possible to perform an offset cancellation within the analog signal processing circuit 200 after the detected amount of offset is subjected to the D/A conversion.

It is possible to omit the offset canceller 302 from the configuration of the PLL circuit 300. In this case, the phase error calculator 303 may be configured to calculate a phase error value based on the digital value output from the A/D converter 301.

A part of the PLL circuit 300 or the entire PLL circuit 300 may be formed on a single semiconductor chip. For example, the offset canceller 302, the phase error calculator 303, the loop filter 304, the phase error range determiner 500 and the synchronization determiner 600, among the configuration of the PLL circuit 300 shown in FIG. 1, may be implemented as a semiconductor integrated circuit.

In the present embodiment, it is described that the operation of the state machine 612 and the operation of the gate generator 613 are shown in FIG. 6. However, these operations are not limited to those shown in FIG. 6.

### Second Embodiment

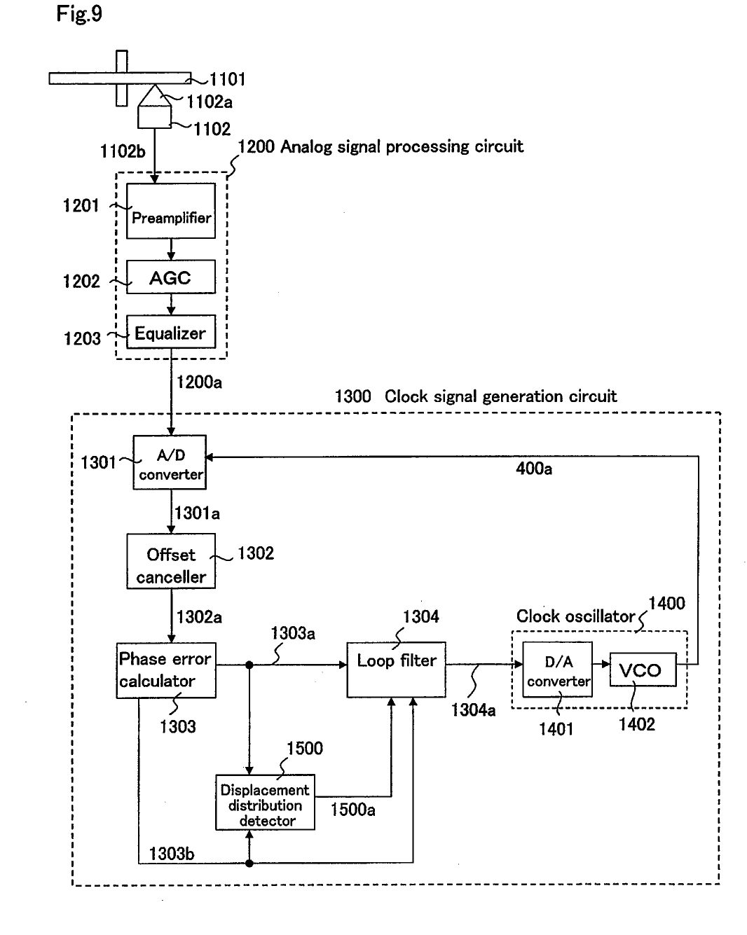

FIG. 9 is a block diagram showing a configuration of a clock signal generation circuit in a second embodiment of the present invention.

The clock signal generation device shown in FIG. 9 generates a clock signal using an optical disc 1101 on which information is recorded. The clock signal generation device includes: an optical head 1102; an analog signal processing circuit 1200; and a clock signal generation circuit 1300.

The optical head 1102 irradiates the optical disc 1101 with a light beam 1102a, detects an amount of the reflected light from the optical disc 1101 and generates an electric signal 1102b based on the amount of the reflected light.

The analog signal processing circuit 1200 extracts a reproduced signal 1200a from the electric signal 1102b. The analog signal processing circuit 1200 includes: a preamplifier 1201 for amplifying the electric signal 1102b; a gain control circuit (AGC) 1202 for controlling the amplitude of the amplified signal to be constant; and an equalizer 1203 for improving a frequency characteristic.

The clock signal generation circuit 1300 functions as a PLL which operates such that a phase difference between the reproduced signal 1200a and the clock signal 1400a becomes closer to zero and it generates the clock signal 1400a which is synchronous with the reproduced sign 1200a.

The clock signal generation circuit 1300 includes: an A/D converter 1301 for digitalizing the reproduced signal 1200a in synchronization with the clock signal 1400a; an offset canceller 1302 which is controlled such that a center level of the digital values 1301a output from the A/D converter 1301 becomes zero; a phase error calculator 1303 for calculating a phase error value 1303a between the digital value 1302a output from the offset canceller 1302 and the clock signal 1400a; a displacement distribution detector 1500 for detecting a deviation of a distribution of displacements of the phase error values 1303a; a loop filter 1304 for removing an unnecessary frequency band component from the phase error value 1303a; and a clock oscillator 1400 for generating the clock signal 1400a having a frequency which is based on the loop filter output value 1304a.

The digital value 1301a by digitalizing the reproduced signal by the A/D converter 1301 includes an unnecessary low frequency band component which remains without being removed in the analog signal processing circuit 1200. The offset canceller 1302 extracts the low frequency band component, and subtracts the extracted offset value from the digital value 1301a so as to remove the low frequency band component. This makes it possible to perform a stable clock generating operation, even if the reproduced signal 1200a is swayed by a low frequency due to dust or finger prints attached on an information recording surface of the optical disc 1101.

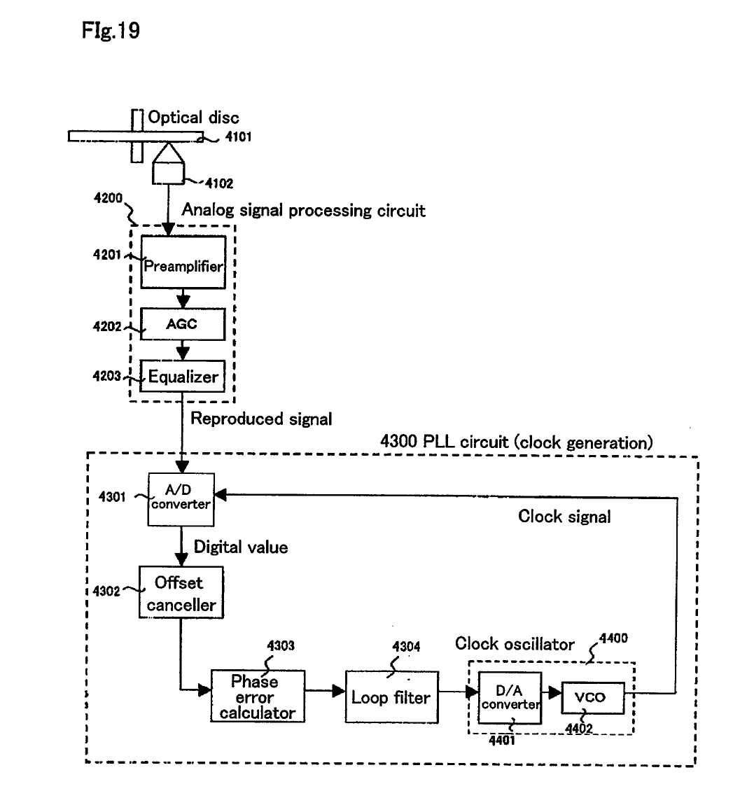

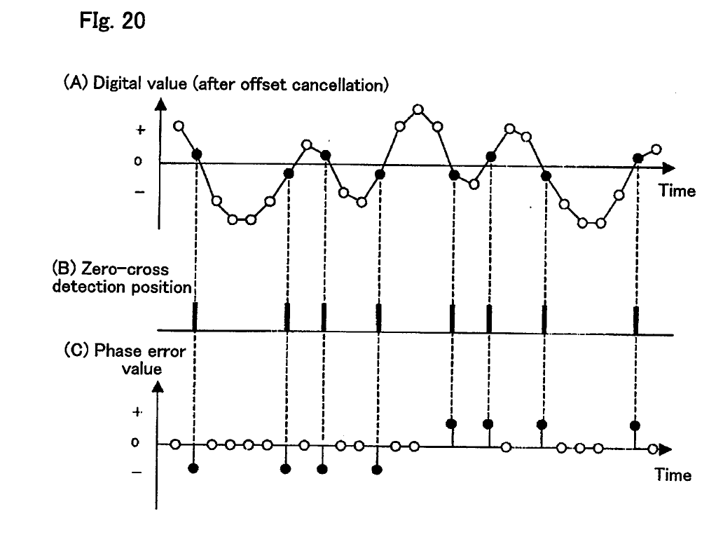

The phase error calculator 1303 calculates a phase error value 1303a from the digital value 1302a after the offset cancellation. The timing of the operation of the phase error calculator 1303 is similar to the timing of the operation of the phase error calculator 303 shown in FIG. 19 (see portion (A) of FIG. 20).

Specifically, the phase error calculator 1303 detects a zero-cross point, determines a position of a digital value which has an absolute value smaller than the other digital value, among two digital values existing before/after the detected zero-cross point, as a zero-cross position (see portion (B) of FIG. 20), outputs the digital value itself as the phase error value when an inclination of the digital value at the zero-cross detection position is of a rising edge, and outputs a value obtained by multiplying the digital value with −1 as the phase error value when an inclination of the digital value at the zero-cross detection position is of a falling edge (see portion (C) of FIG. 20).

An unnecessary frequency band component is removed from the phase error value 1303a by the loop filter 1304. The output value of the loop filter 1304 is input to the clock oscillator 1400. The clock oscillator 1400 includes: a D/A converter 1401 for converting the output value 1304a of the loop filter 1304 into a voltage signal; and a voltage control oscillator (VCO) 1402. The frequency of the clock signal 1400a generated by the VCO 1402 becomes higher as the output value 1304a of the loop filter 1304 increases and the output voltage of the D/A converter 1401 becomes higher. The frequency of the clock signal 1400a generated by the VCO 1402 becomes lower as the output value 1304a of the loop filter 1304 decreases and the output voltage of the D/A converter 1401 becomes lower. Accordingly, the PLL operates to increase the frequency of the clock signal 1400a when the phase error value 1303a calculated by the phase error calculator 1303 is a positive value, and the PLL operates to decrease the frequency of the clock signal 1400a when the phase error value 1303a calculated by the phase error calculator 1303 is a negative value.

Next, a displacement distribution detector 1500 will be described in detail.

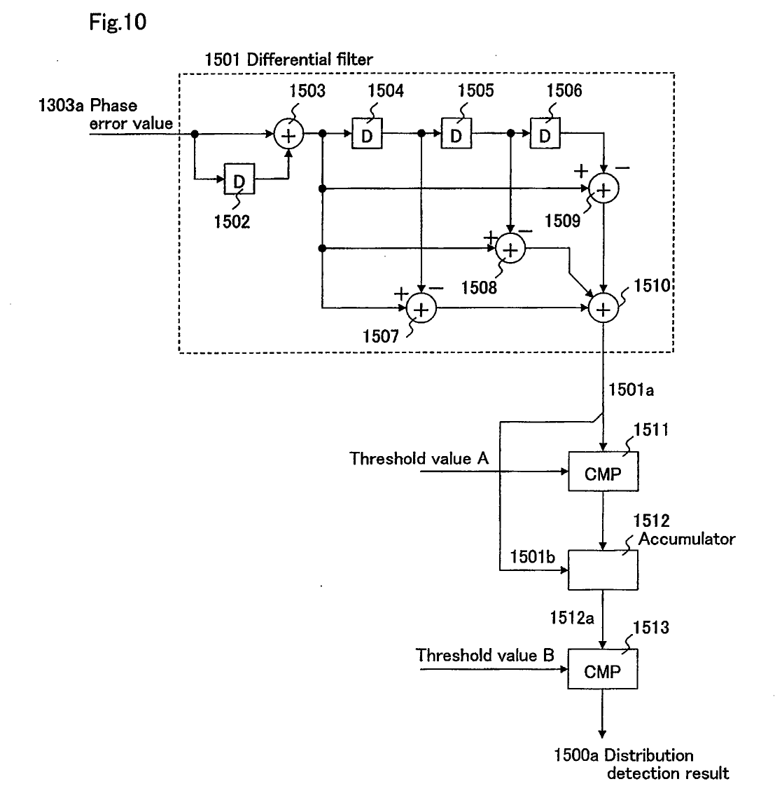

FIG. 10 is a block diagram showing a configuration of the displacement distribution detector 1500. The displacement distribution detector 1500 includes: a differential filter 1501 for obtaining a displacement (a differential filter output value 1501a) by differentiating the phase error value 1303a; and a circuit for detecting a deviation of a distribution of the differential filter output values 1501a.

In the differential filter 1501, the delay unit 1502 latches and holds the phase error value 1303a each time the phase error calculator 1303 calculates the phase error. The adder 1503 adds the phase error value 1303a to the phase error value 1303a held by the delay unit 1502 so as to remove a noise component of the phase error value 1303a and to improve its resolution. Each of the delay units 1504, 1505 and 1506 latches and holds the output value of the adder 1503 each time the phase error calculator 1303 calculates the phase error. Each of the subtracters 1507, 1508 and 1509 performs differentiation between the output of the adder 1503 and a corresponding one of the outputs of the delay units 1504, 1505 and 1506. The adder 1510 adds the three differential values so as to remove a noise component of the differentiation result and to improve its resolution.

The comparator 1511 compares in absolute value the differential filter output value 1501a with a predetermined threshold value A. When the differential filter output value 1501a is greater than the predetermined threshold value A, the accumulator 1512 performs an accumulation according to a sign 1501b of the differential filter output value 1501a. If the sign 1501b is positive, an addition of +1 is applied to the accumulated value 1512a. If the sign 1501b is negative, a subtraction of −1 is applied to the accumulated value 1512a. When the differential filter output value 1501a is smaller than the predetermined threshold value A in the comparison by the comparator 1511, the accumulator 1512 performs the addition or the subtraction such that the absolute value of the accumulated value 1512a becomes smaller. If the accumulated value 1512a is negative, an addition of +1 is applied to the accumulated value 1512a. If the accumulated value 1512a is positive, a subtraction of −1 is applied to the accumulated value 1512a. This makes it possible to gradually increases the accumulated value 1512a to the positive side if the differential filter output value 1501a is deviated to the positive side. This also makes it possible to gradually increase the accumulated value 1512a to the negative side if the differential filter output value 1501a is deviated to the negative side. When the absolute value of the differential filter output value 1501a is small, the accumulated value 1512a is maintained at a value which is close to zero.

The comparator 1513 compares in absolute value the accumulated value 1512a with a predetermined threshold value B, and outputs the comparison result as a distribution detection result 1500a. When the accumulated value 1512a is smaller than the predetermined threshold value B, the comparator 1513 outputs a value (e.g., 0) indicating that no deviation exists in the distribution of the differential filter output values 1501a as the distribution detection result 1500a. It is assumed that the accumulated value 1512a is greater than the predetermined threshold value B. In this case, the comparator 1513 outputs a value (e.g., −1) indicating that a deviation to the negative side exists in the distribution of the differential filter output values 1501a as the distribution detection result 1500a if the accumulated value 1512a is negative, and the comparator 1513 outputs a value (e.g., +1) indicating that a deviation to the positive side exists in the distribution of the differential filter output values 1501a as the distribution detection result 1500a if the accumulated value 1512a is positive.

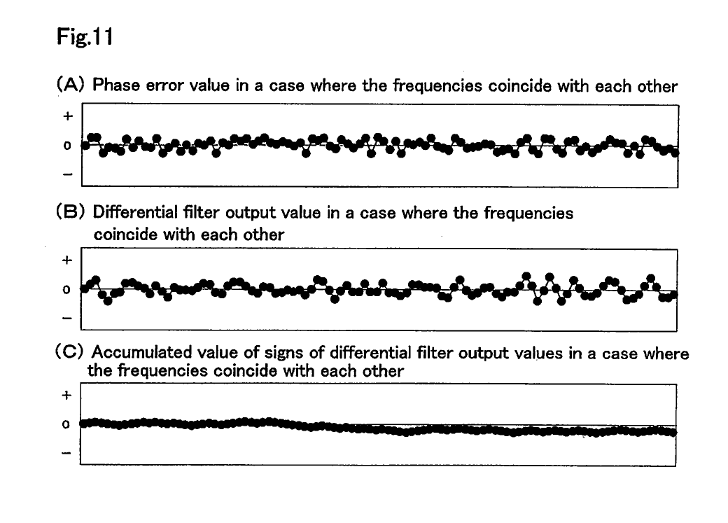

FIGS. 11, 12 and 13 are timing diagrams showing the operation of the displacement distribution detector 1500.

FIG. 11 shows the operation in a case where the frequency of the reproduced signal 1200a and the frequency of the clock signal 1400a almost coincide with each other in a range where the PLL can capture. Portion (A) of FIG. 11 shows a change in the phase error value 1303a along the time axis. Portion (B) of FIG. 11 shows a change in the differential filter output value 1501a along the time axis. Portion (C) of FIG. 11 shows a change in the accumulated value 1512a along the time axis. In a case where the frequencies almost coincide with each other, the phase error values 1303a are dispersed in the vicinity of zero due to influences of a noise component of the reproduced signal 1200a and a jitter component of the clock signal 1400a (see portion (A) of FIG. 11). Accordingly, the differential filter output values 1501a are not deviated to either the positive or negative side and are dispersed in the vicinity of zero (see portion (B) of FIG. 11), and the accumulated values 1512a are maintained at a value in the vicinity of zero (see portion (C) of FIG. 11).

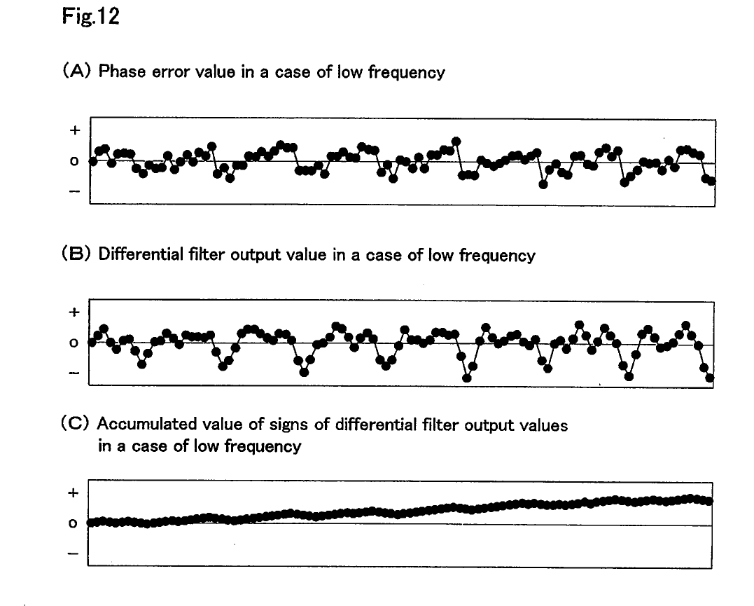

FIG. 12 shows the operation in a case where the frequency of the clock signal 1400a is shifted to the lower side relative to the reproduced signal 1200a by an amount where the PLL cannot capture.

Portion (A) of FIG. 12 shows a change in the phase error value 1303a along the time axis. Portion (B) of FIG. 12 shows a change in the differential filter output value 1501a along the time axis. Portion (C) of FIG. 12 shows a change in the accumulated value 1512a along the time axis.

In a case where the frequency of the clock signal 1400a is lower, the phase error values 1303a are dispersed in a higher frequency band due to influences of a noise component of the reproduced signal 1200a and a jitter component of the clock signal 1400a, and the phase error values 1303a have a saw tooth shaped low frequency component with an inclination rising rightward (see portion (A) of FIG. 12). Accordingly, the differential filter output value 1501a generally takes a positive value in an interval where a change in the phase error value 1303a increases rightward, while the differential filter output value 1501a generally takes a negative value in an interval where the phase error value rapidly decreases (see portion (B) of FIG. 12). Since the change in the phase error value 1303a increases rightward in most intervals, the accumulated value 1512a is gradually increased to the positive side (see portion (C) of FIG. 12). This makes it possible to detect that the frequency of the clock signal 1400a is shifted to the lower side by an amount where the PLL cannot capture.

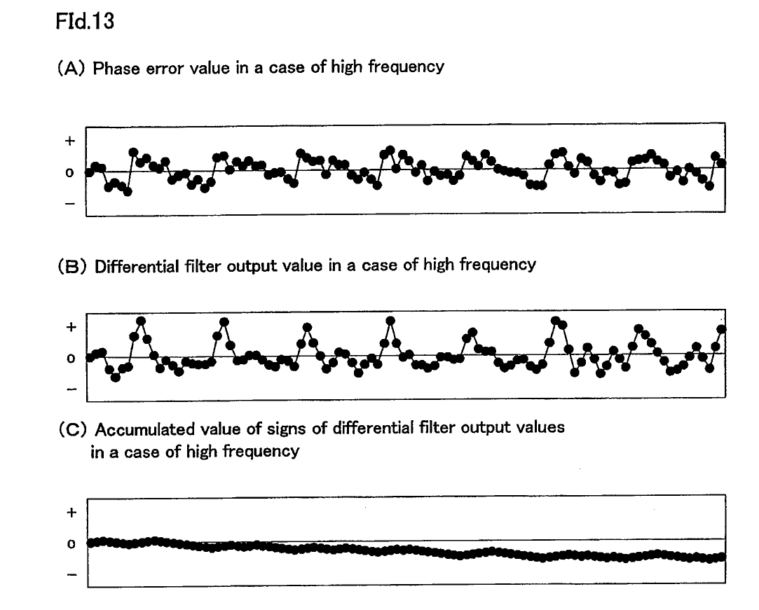

FIG. 13 shows operation in a case where the frequency of the clock signal 1400a is shifted to the higher side relative to the reproduced signal 1200a by an amount where the PLL cannot capture.

Portion (A) of FIG. 13 shows a change in the phase error value 1303a along the time axis. Portion (B) of FIG. 13 shows a change in the differential filter output value 1501a along the time axis. Portion (C) of FIG. 13 shows a change in the accumulated value 1512a along the time axis.

In a case where the frequency of the clock signal 1400a is higher, the phase error values 1303a are dispersed in a higher frequency band due to influences of a noise component of the reproduced signal 1200a and a jitter component of the clock signal 1400a, and the phase error values 1303a have a saw tooth shaped low frequency component with an inclination falling rightward (see portion (A) of FIG. 13). Accordingly, the differential filter output value 1501a generally takes a negative value in an interval where a change in the phase error value 1303a decreases rightward, while the differential filter output value 1501a generally takes a positive value in an interval where the phase error value 1303a rapidly increases (see portion (B) of FIG. 13). Since the change in the phase error value 1303a decreases rightward in most intervals, the accumulated value 1512a is gradually increased to the negative side (see portion (C) of FIG. 13). This makes it possible to detect that the frequency of the clock signal 1400a is shifted to the higher side by an amount where the PLL cannot be captured.

The phase error values 1303a are dispersed depending on the quality of the reproduced signal 1200a and the jitter component of the clock signal 1400a, as shown in portion (A) of FIG. 11 to portion (A) of FIG. 13. However, it is possible to exactly detect a direction of deviation in frequency in a case where the PPL cannot capture, as shown in portion (C) of FIG. 11 to portion (C) of FIG. 13, since the accumulator 1512 performs the accumulation.

Next, the operation of the loop filter 1304 will be described in detail.

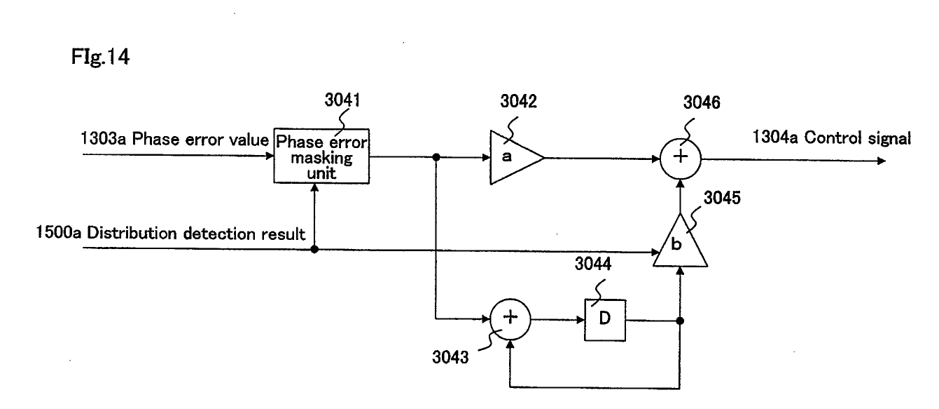

FIG. 14 is a block diagram showing a configuration of the loop filter 1304.

The loop filter 1304 includes: a phase error masking unit 3041 for masking a value of the phase error value 1303a according to the distribution detection result 1500a; an amplifier 3042 for obtaining a value “a” times as large as the phase error value after mask operation; an adder 3043 and a delay unit 3044 for accumulating the phase error values after the masking operation each time the phase error is calculated; an amplifier 3045 for obtaining a value “b” times as large as the accumulated value of the phase error values; and an adder 3046 for adding the output values of two amplifiers 3042 and 3045. A control signal 1304a output from the adder 3046 is input to the clock oscillator 1400.

In a case where the distribution detection result 1500a indicates that the distribution of the differential filter output values is not deviated, the phase error masking unit 3041 outputs the phase error value 1303a.

In a case where the distribution detection result 1500a indicates that the distribution of the differential filter output values is deviated to the positive side, the phase error masking unit 3041 outputs the phase error value 1303a if the phase error value 1303a is a positive value, and the phase error masking unit 3041 does not output the phase error value 1303a by masking if the phase error value 1303a is a negative value.

In a case where the distribution detection result 1500a indicates that the distribution of the differential filter output values is deviated to the negative side, the phase error masking unit 3041 outputs the phase error value 1303a if the phase error value 1303a is a negative value, and the phase error masking unit 3041 does not output the phase error value 1303a by masking if the phase error value 1303a is a positive value.

For the phase error value after the masking operation, the amplifier 3042 performs the phase adjustment for the clock signal 1400a, and the adder 3043, the delay unit 3044 and the amplifier 3045 included in the accumulator performs the frequency adjustment for the clock signal 1400a.

In a case where the masking operation is performed by the phase error masking unit 3041, only a positive phase error value is output if the frequency of the clock signal 1400a is low. Accordingly, the frequency of the clock signal 1400a monotonously increases toward the frequency of the reproduced signal 1200a. If the frequency of the clock signal 1400a is high, only a negative phase error value is output. Accordingly, the frequency of the clock signal 1400a monotonously decreases toward the frequency of the reproduced signal 1200a. As a result, if the frequency enters into a range where the frequencies almost coincide with each other, no masking operation is performed, the phase adjustment is performed and the clock signal 1400a which is synchronous in phase with the reproduced signal 1200a is obtained. Moreover, in a case where the distribution detection result 1500a indicates that there is a positive or negative deviation, it is possible to further shorten the lead-in time for the frequency by increasing the magnitude of “b” in the amplifier 3045.

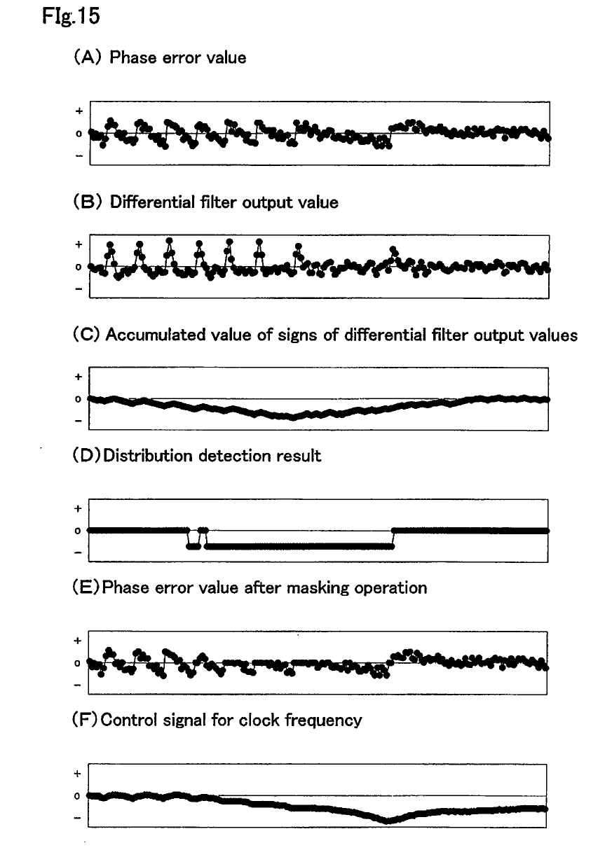

FIG. 15 is a timing diagram showing the operations of the displacement distribution detector 1500 and the loop filter 1304 in a case where the frequency of the clock signal 1400a is deviated toward the higher side relative to the reproduced signal 1200a by an amount where the PLL cannot capture.

Portion (A) of FIG. 15 shows a change in the phase error value 1303a along the time axis. Portion (B) of FIG. 15 shows a change in the differential filter output value 1501a along the time axis. Portion (C) of FIG. 15 shows a change in the accumulated value 1512a along the time axis. Portion (D) of FIG. 15 shows a change in the distribution detection result 1500a along the time axis. Portion (E) of FIG. 15 shows a change in the output value of the phase error masking unit along the time axis. Portion (F) of FIG. 15 shows a change in the control signal 304a along the time axis.

Since the frequency of the clock signal 1400a is in a higher state where the PLL cannot capture in a first half part, the phase error value (A) has a saw tooth shaped waveform with an inclination falling rightward, the differential filter output value (B) is generally a negative value, the accumulated value (C) of signs increases to the negative side. If the absolute value of the accumulated value (C) of signs exceeds a predetermined threshold value B, the distribution detection result (D) becomes a value (e.g., −1) indicating that there exists a deviation to the negative side. In an interval where the distribution detection result (D) is −1, a positive value of the phase error values (A) is masked in the phase error masking unit 3041. As a result, only a negative value is output as shown in phase error value (E) after the masking operation. As a result, the control signal (F) for the clock frequency, which initially has a value in the vicinity of zero when the PLL cannot capture, is controlled such that the frequency of the clock signal 1400a is decreased.

When the frequency of the clock signal 1400a approaches the frequency of the reproduced signal 1200a to some extent, the inclination of the saw tooth shaped waveform of the phase error value (A) is decreased, and the frequency in which the absolute value of the differential filter output value (B) exceeds a predetermined threshold value A is decreased. As a result, the absolute value of the accumulated value (C) of signs tends to decrease. When the absolute value of the accumulated value (C) of signs becomes lower than a predetermined threshold value B, it is determined that a deviation of the distribution becomes smaller. Then, the distribution detection result (D) takes a value (e.g., 0) indicating that there is no deviation. As a result, no masking operation is performed by the phase error masking unit 3041 and the phase error value (A) is output as it is. In this state, the frequency error between the reproduced signal 1200a and the clock signal 1400a is within a range where the PLL can capture. Accordingly, it is possible to control the control signal (F) for the clock frequency in a stable state where the clock signal 1400a is synchronous in phase with the reproduced signal 1200a.

According to the second embodiment of the present invention, as described above, it is possible to exactly detect a state where the PLL cannot capture the frequency error between the reproduced signal and the clock signal, even if the quality of the reproduced signal is bad. By controlling the frequency of the clock signal in accordance with the detection result such that the frequency error is within a capture range, it is possible to generate a stable clock signal.

By obtaining the distribution of displacements of the phase error values using an accumulated value obtained by accumulating the signs of displacements of the phase error values, it is possible to realize a high precision detection with a small scale circuit, without the necessity for holding many phase error values.

It is possible to omit the offset canceller 1302 from the configuration of the clock signal generation circuit 1300. In this case, the phase error calculator 1303 may be configured to calculate the phase error value based on the digital value output from the A/D converter 1301.

A part of the clock signal generation circuit 1300 or the entire clock signal generation circuit 1300 may be formed on a single semiconductor chip. For example, the offset canceller 1302, the phase error calculator 1303, the loop filter 1304 and the displacement distribution detector 1600, among the configuration of the clock signal generation circuit 1300 shown in FIG. 9, may be implemented as a semiconductor integrated circuit.

It is possible to provide a synchronization determiner 600a in the clock signal generation circuit 1300, which has a configuration similar to that of the synchronization determiner 600 described in the first embodiment. In this case, the validity or the invalidity of the displacement distribution detection may be controlled using the synchronization determiner 600a. For example, in a case where the synchronization determiner 600a determines that the reproduced signal and the clock signal are not synchronous with each other, the detection by the displacement distribution detector 1500 is determined as being valid, while in a case where the synchronization determiner 600a determines that the reproduced signal and the clock signal are synchronous with each other, the detection by the displacement distribution detector 1500 is determined as being invalid.

In a case where an error is detected, the synchronization determiner 600a may determine that the reproduced signal and the clock signal are not synchronous with each other, in a similar way as the synchronization determiner 600.

It is possible to control the offset canceller 1302 such that the gain of the offset canceller 1302 becomes higher in a case where the synchronization determiner 600a determines that the reproduced signal and the clock signal are not synchronous with each other in a similar way as the synchronization determiner 600. It is possible to control the offset canceller 1302 such that the gain of the offset canceller 1302 becomes lower in a case where the synchronization determiner 600a determines that the reproduced signal and the clock signal are synchronous with each other in a similar way as the synchronization determiner 600.

### Third Embodiment

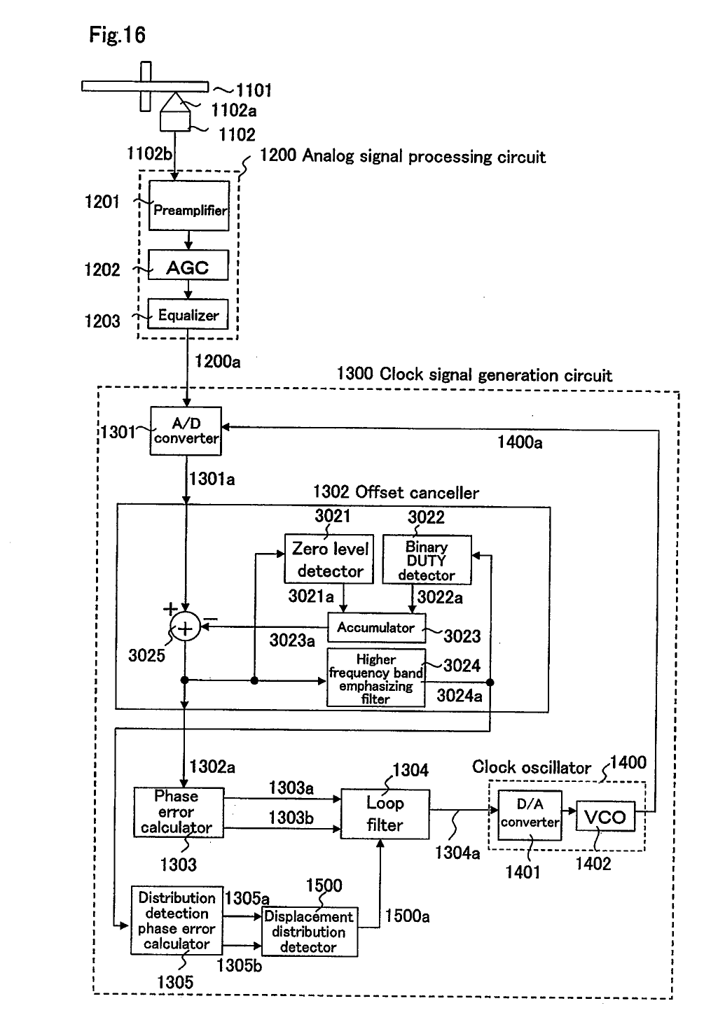

FIG. 16 is a block diagram showing a configuration of the clock signal generation circuit in a third embodiment of the present invention. In FIG. 16, the same reference numerals are given to the elements which are the same as those shown in FIG. 9, and the descriptions of those elements will be omitted.

The offset canceller 1302 is controlled such that a center level of the digital value 1301a output from the A/D converter 1301 becomes zero. The offset canceller 1302 includes: a zero level detector 3021; binary DUTY detector 3022; an accumulator 3023, a subtracter 3025; and a higher frequency band emphasizing filter 3024.

The higher frequency band emphasizing filter 3024 outputs a higher frequency band emphasizing filter output value 3024a which is obtained by emphasizing a higher frequency band component of the digital value 1302a after the offset cancellation. For example, a short mark, such as 2T or 3T where the amplitude can be easily reduced, or a short space portion is amplified.

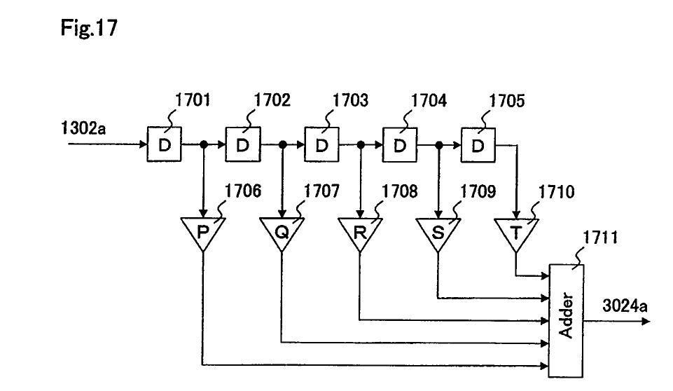

FIG. 17 shows an exemplary configuration of a higher frequency band emphasizing filter. The higher frequency band emphasizing filter shown in FIG. 17 is a 5-order FIR filter. The delay units 1701, 1702, 1703, 1704 and 1705 delays the input digital value 1302a in synchronization with the clock signal 1400a. The values from the delay units are input to the respective multipliers 1706, 1707, 1708, 1709 and 1710. The five multiplied values is added by the adder 1711 so as to output an added value 3024a. The coefficients of the five multipliers P, Q, R, S and T may be, for example, P=2, Q=−18, R=63, S=−18 and T=2.

The zero level detector 3021 extracts a zero-cross point from the digital value 1302a after the offset cancellation, determines a digital value which has an absolute value smaller than that of the other digital value among the two digital values between which the zero-cross point is sandwiched, as a zero-cross position, and outputs the digital value as a zero-cross detection value 3021a, in a similar way as the phase error calculator 1303.

The binary DUTY detector 3022 outputs a binary detection value 3022a obtained by binarizing the higher frequency band emphasizing filter output value 3024a so as to take two values which have the same absolute value and have opposite polarities. For example, if the higher frequency band emphasizing filter output value 3024a is a positive value, the binary detection value is +1, while if the higher frequency band emphasizing filter output value 3024a is a negative value, the binary detection value is −1.

The accumulator 3023 accumulates a value obtained by adding the zero level detection value 3021a with the binary detection value 3022a, and outputs the accumulated value as a binary level value 3023a.

The subtracter 3025 subtracts the binary level value 3023a from the digital value 1301a.

According to the loop configuration described above, it is possible to control the binary level value 3023a such that the binary level value 3023a gradually approaches zero. As a result, it is possible to remove variation component in a lower frequency band included in the digital value 1301a.

The distribution detection phase error calculator 1305 performs the operation which is similar to that of the phase error calculator 1303. The distribution detection phase error calculator 1305 receives the higher frequency band emphasizing filter output value 3024a as an input, and outputs the distribution detection phase error calculation value 1305a and the distribution detection phase error calculation timing signal 1305b to the displacement distribution detector 1500.

According to the third embodiment of the present invention, as described above, it is possible to improve a precision in binarization and a detection precision of the zero-cross point using the higher frequency band emphasizing filter 3024, even if the amplitude of the higher frequency band component of the reproduced signal 1200a is small and the S/N is low. As a result, it is possible to perform a stable offset cancel control and a stable phase error distribution detection.

In the third embodiment of the present invention, the 5-order FIR filter is employed as a higher frequency band emphasizing filter. Alternatively, a waveform equalizer as shown in Reference 5 and Reference 6 described above, or a maximum likelihood decoder as shown in Reference 7 described above may be employed as a higher frequency band emphasizing filter, for example.

### Fourth Embodiment

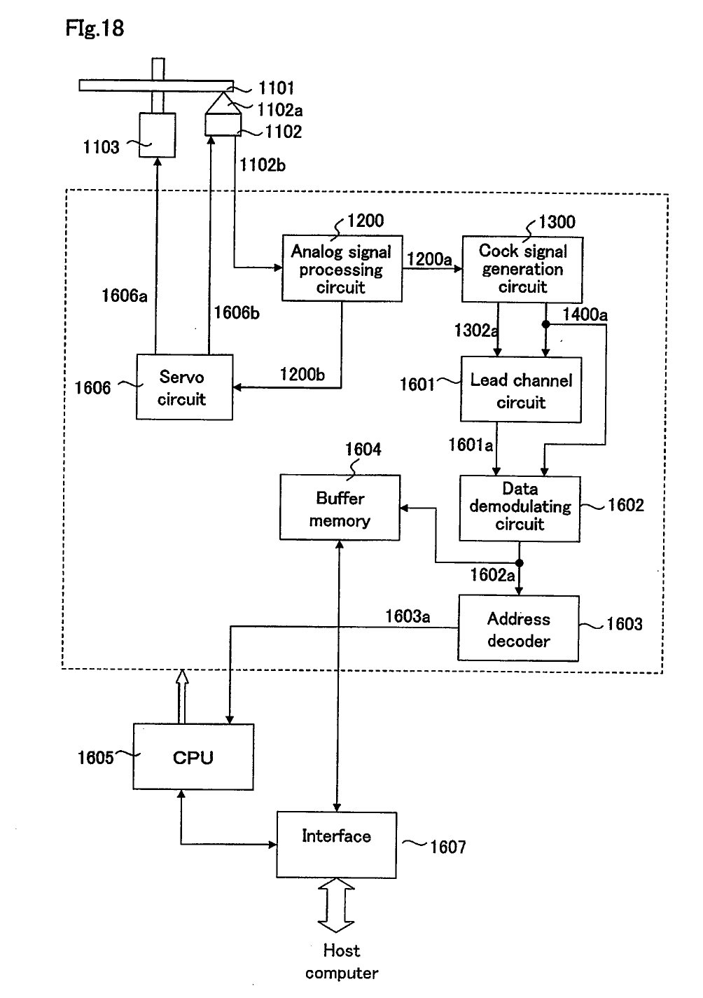

FIG. 18 is a block diagram showing a configuration of a disc device in a fourth embodiment of the present invention. In FIG. 18, the same reference numerals are given to the elements which are the same as those shown in FIG. 9, and the descriptions of those elements will be omitted.

The disc device includes: an optical head 1102 for irradiating an optical disc 1101 with a laser 1102a; a motor 1103 for rotating the optical disc 1101; a servo circuit 1606 for controlling the motor 1103 and the optical head 1102; an analog signal processing circuit 1200 for extracting a data reproduced signal 1200a and a servo reproduced signal 1200b from an electric signal 1102b obtained by the optical head 1102; a clock signal generation circuit 1300 which is described in the second and third embodiments; a lead channel circuit 1601 for extracting reproduced data 1601a from a digital value 1302a; a data demodulating circuit 1602 for demodulating the reproduced data 1601a; and an address decoder 1603 for extracting address information 1603a from a data demodulation result 1602a; a buffer memory 1604 for storing the data demodulation result 1602a; a CPU 1605 for controlling the entire system; and an interface circuit 1607 with an external host computer.

A laser emitted from the optical head 1102 is converged onto a track of the optical disc 1101. The optical head 1102 detects an amount of the reflected light from the optical disc 1101 so as to output an electric signal 1102b. The analog signal processing circuit 1200 extracts a reproduced signal 1200a corresponding to information recorded on the optical disc 1101 and a servo reproduced signal 1200b corresponding to a scanning state for a track formed on the optical disc 1101 from the electric signal 1102b.

The servo circuit 1606 performs the control using the servo reproduced signal 1200b such that the rotation number of the motor 1103, a light convergence state of the laser in the optical head 1102 and a scanning state on the track become optimal states.

The clock signal generation circuit 1300 extracts a clock signal 1400a which is synchronous with the reproduced signal 1200a, and outputs a digital value 1302a obtained by sampling the reproduced signal 1200a in synchronization with the clock signal 1400a.

The lead channel circuit 1601 extracts reproduced data 1601a obtained by binarizing the digital value 1302a. The reproduced data 1601a is demodulated in the data demodulating circuit 1602. As a result, it is possible to obtain digital information recorded on the optical disc 1101.

The address decoder 1603 extracts an address value 1603a included in the demodulation result 1602a and transmits the address value 1603a to the CPU 1605.

The CPU 1605 controls the reproduction operation while obtaining the address value 1603a and inputs and/or outputs information with the host computer through the interface 1607.

According to the fourth embodiment of the present invention, as described above, by using the clock signal generated by the clock signal generation circuit described in the second and third embodiments, it is possible to reproduce digital information in a stable state, even if the quality of the reproduced signal becomes bad due to the degrade of the quality of the optical disc 1101 and/or the degrade of the performance of the optical head 1102.

The clock signal generation device of the present invention can be implemented as an LSI, which is an integrated circuit. The elements included in the clock signal generation device may be formed on the respective chips individually. Alternatively, a part of the elements or the entire elements may be formed on a single chip.

Herein, an integrated circuit is referred to as an LSI. However, an integrated circuit may be referred to as an IC, a system LSI, a super LSI or a ultra LSI depending on the degree of integration.

The integrated circuit according to the present invention is not limited to an LSI and it may be implemented as a dedicated purpose circuit or a general purpose processor. A FPGA (Field Programmable Gate Array) which is programmable after the LSI is fabricated, a reconfigurable processor capable of reconfiguring connections or settings of circuit cells within the LSI may be employed.

Further, if a technology for implementing an integrated circuit replacing an LSI, which will be created as a result of progress in the semiconductor technology or a different technology which is branched from the semiconductor technology, comes to be available, it is possible to integrate a plurality of functional blocks using such technologies. There is a possibility that any biotechnology or the like can be applied.

As described above, the present invention is exemplified by the use of its preferred embodiments. However, the present invention should not be interpreted solely based on embodiments described above. It is understood that the scope of the present invention should be interpreted solely based on the claims. It is also understood that those skilled in the art can implement equivalent scope of technique, based on the description of the present invention and common knowledge from the description of the detailed preferred embodiments of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention provides an effect that it is possible to immediately generate a synchronized clock signal, even if an abnormal state occurs. The abnormal state includes, for example, a state where the frequency of the reproduced signal is changed rapidly or a state where the amplitude of the reproduced signal is temporality reduced. The present invention is useful for a PLL circuit which is used in reproducing data recorded on an optical disc device or the like.

The present invention provides an effect that it is possible to immediately generate a synchronized clock signal, even if the frequency of the reproduced signal is apart from the frequency of the clock signal and the quality of the reproduced signal is bad. The present invention is useful for a clock signal generation circuit which is used in reproducing data recorded on an optical disc device or the like.

1. A clock signal generation device for generating a clock signal which is synchronous with a reproduced signal from an optical disc on which information is recorded, comprising:
an A/D converting means for sampling the reproduced signal in response to the clock signal and for converting the sampled reproduced signal into a digital value so as to generate a plurality of digital values sequentially in time;
a phase error calculating means for calculating a phase error value indicating a phase error between the reproduced signal and the clock signal based on each of the plurality of digital values;
a loop filter means for outputting a control signal controlling a frequency of the clock signal based on the phase error value;
a clock oscillating means for generating a signal having a frequency corresponding to the control signal as the clock signal; and
a phase error range determining means for determining whether or not the phase error is within a predetermined range based on the phase error value,
wherein the phase error calculating means detects zero-cross points of the plurality of digital values, calculates the phase error value based on a digital value which is closer to the zero level among two digital values between the zero-cross points when it is determined that the phase error is within the predetermined range by the phase error range determining means, and calculates the phase error value based on a digital value which is further from the zero level among the two digital values when it is determined that the phase error is not within the predetermined range by the phase error range determining means.

2. A clock signal generation device according to claim 1, wherein:
the phase error range determining means includes a low-pass filter means for smoothing the phase error value and
the phase error range determining means determines whether or not the phase error is within the predetermined range based on a result of comparison between an output value of the low-pass filter means and a predetermined threshold value.

3. A clock signal generation device according to claim 1, wherein:
the phase error range determining means controls the loop filter means such that a gain of the loop filter means becomes higher when it is determined that the phase error is not within the predetermined range.

4. A clock signal generation device according to claim 1, further comprising: a synchronization determining means for determining whether or not the reproduced signal and the clock signal are synchronous with each other based on the amplitude of the control signal, and
wherein:
the synchronization determining means makes the determination by the phase error range determining means valid, when it is determined that that the reproduced signal and the clock signal are not synchronous with each other, and
the synchronization determining means makes the determination by the phase error range determining means invalid, when it is determined that the reproduced signal and the clock signal are synchronous with each other.

5. A clock signal generation device according to claim 1, further comprising: an offset canceling means for detecting a level at which the digital value is binarized and for canceling an offset component of the digital value based on the level,
wherein the phase error calculating means calculates the phase error value based on the digital value where the offset component of the digital value has been cancelled by the offset canceling means.

6. A clock signal generation device according to claim 5, further comprising: a synchronization determining means for determining whether or not the reproduced signal and the clock signal are in synchronous with each other based on the amplitude of the control signal, and
wherein:
the synchronization determining means controls the offset canceling means such that a gain of the offset canceling means becomes higher, when it is determined that the reproduced signal and the clock signal are not synchronous with each other, and
the synchronization determining means controls the offset canceling means such that a gain of the offset canceling means becomes lower, when it is determined that the reproduced signal and the clock signal are synchronous with each other.

7. A clock signal generation device according to claim 4, further comprising:
an accumulation means for accumulating the digital values over each of predetermined intervals;
an averaging means for averaging the accumulated values by the accumulation means; and
an error detecting means for detecting an error when a difference between the accumulated value by the accumulation means and the average value by the averaging means is larger than a predetermined threshold value,
wherein the synchronization determining means determines that the signals are not synchronous with each other when an error is detected by the error detecting means.

8. A semiconductor integrated circuit used in a clock signal generation device for generating a clock signal which is synchronous with a reproduced signal from an optical disc on which information is recorded, wherein the clock signal generation device includes an A/D converting means for sampling the reproduced signal in response to the clock signal and for converting the sampled reproduced signal into a digital value so as to generate a plurality of digital values sequentially in time; and a clock oscillating means for generating the clock signal,
the semiconductor integrated circuit comprising:
a phase error calculating means for calculating a phase error value indicating a phase error between the reproduced signal and the clock signal based on each of the plurality of digital values;
a loop filter means for outputting a control signal controlling a frequency of the clock signal based on the phase error value; and
a phase error range determining means for determining whether or not the phase error is within a predetermined range based on the phase error value,
wherein:
the phase error calculating means detects zero-cross points of the plurality of digital values, calculates the phase error value based on a digital value which is closer to the zero level among two digital values between the zero-cross points when it is determined that the phase error is within the predetermined range by the phase error range determining means, and calculates the phase error value based on a digital value which is further from the zero level among the two digital values when it is determined that the phase error is not within the predetermined range by the phase error range determining means, and
the clock oscillating means generates a signal having a frequency corresponding to the control signal as the clock signal.

9. A data reproduction method for generating a clock signal which is synchronous with a reproduced signal from an optical disc on which information is recorded and for outputting reproduced data obtained by digitizing the reproduced signal in synchronization with the clock signal, the data reproduction method comprising the steps of:
(a) sampling the reproduced signal in response to the clock signal and converting the sampled reproduced signal into a digital value so as to generate plurality of digital values in the order of time sequence;
(b) calculating a phase error value indicating a phase error between the reproduced signal and the clock signal based on each of the plurality of digital values;
(c) outputting a control signal controlling a frequency of the clock signal based on the phase error value;
(d) generating a signal having a frequency corresponding to the control signal as the clock signal; and
(e) determining whether or not the phase error is within a predetermined range based on the phase error value,
wherein the step (b) includes the steps of:
detecting zero-cross points of the plurality of digital values;
calculating the phase error value based on a digital value which is closer to the zero level among two digital values between the zero-cross points when it is determined that the phase error is within the predetermined range in the phase error range determining step; and
calculating the phase error value based on a digital value which is further from the zero level among the two digital values when it is determined that the phase error is not within the predetermined range in the phase error range determining step.

10. A clock signal generation device for generating a clock signal which is synchronous with a reproduced signal from a disc on which information is recorded, comprising:
an A/D converting means for sampling the reproduced signal in response to the clock signal and for converting the sampled reproduced signal into a digital value so as to generate a plurality of digital values in the order of time sequence;
a first phase error calculating means for calculating a first phase error value indicating a phase error between the reproduced signal and the clock signal based on each of the plurality of digital values;
a first displacement distribution detecting means for detecting a distribution of displacements of the first phase error values;
a loop filter means for generating a control signal controlling a frequency of the clock signal based on the first phase error values and a detection result of the distribution of displacements of the first phase error values; and
a clock oscillating means for generating a signal having a frequency corresponding to the control signal as the clock signal,
wherein the loop filter means generates the control signal such that a deviation of the distribution of displacements of the first phase error values becomes smaller.

11. A clock signal generation device according to claim 10, further comprising:
a synchronization determining means for determining whether or not the reproduced signal and the clock signal are synchronous with each other based on the amplitude of the control signal,
wherein:
the synchronization determining means makes the detection by the first displacement distribution detecting means valid, when it is determined that the reproduced signal and the clock signal are not synchronous with each other, and
the synchronization determining means makes the detection by the first displacement distribution detecting means invalid, when it is determined that the reproduced signal and the clock signal are synchronous with each other.

12. A clock signal generation device according to claim 11, further comprising:
an accumulation means for accumulating the digital values over each of predetermined intervals;
an averaging means for averaging the accumulated values by the accumulation means; and
an error detecting means for detecting an error when a difference between the accumulated value by the accumulation means and the average value by the averaging means is larger than a predetermined threshold value,
wherein the synchronization determining means determines that the signals are not synchronous with each other when an error is detected by the error detecting means.

13. A clock signal generation device according to claim 10, wherein the loop filter means uses only values having polarity where the deviation of the distribution of displacements of the first phase error values becomes smaller, when the deviation of the distribution is large.

14. A clock signal generation device according to claim 10, wherein the displacement distribution detecting means detects the distribution by accumulating signs of the displacements.

15. A clock signal generation device according to claim 14, wherein the displacement distribution detecting means accumulates the signs of the displacements only when the absolute value of the displacement is larger than a predetermined value.

16. A clock signal generation device according to claim 15, wherein the displacement distribution detecting means increases or decreases accumulated values of the signs of the displacements such that the absolute value of the accumulated values becomes smaller, when the absolute value of the displacement is smaller than a predetermined value.

17. A clock signal generation device according to claim 10, further comprising:
a higher frequency band emphasizing filter means for emphasizing a higher frequency band component of a digital value;
a second phase error calculating means for calculating a second phase error value indicating a phase error between the reproduced signal and the clock signal based on an output signal of the higher frequency band emphasizing filer means; and
a second displacement distribution detecting means for detecting a distribution of displacements of the second phase error values,
wherein the loop filter means generates the control signal such that a deviation of the distribution of displacements of the second phase error values becomes smaller.

18. A clock signal generation device according to claim 17, further comprising:
an offset canceling means for detecting a level at which the digital value is binarized and for canceling an offset component of the digital value based on the level,
wherein:
the first phase error calculating means calculates the first phase error value based on the digital value where the offset component of the digital value has been cancelled by the offset canceling means, and
the high frequency band emphasizing filter means is included in the offset canceling means.

19. A clock signal generation device according to claim 18, further comprising:
a synchronization determining means for determining whether or not the reproduced signal and the clock signal are synchronous with each other based on the amplitude of the control signal,
wherein:
the synchronization means controls the offset canceling means such that a gain of the offset canceling means becomes higher, when it is determined that the reproduced signal and the clock signal are not synchronous with each other, and
the synchronization means controls the offset canceling means such that a gain of the offset canceling means becomes lower, when it is determined that the reproduced signal and the clock signal are synchronous with each other.

20. A semiconductor integrated circuit used in a clock signal generation device for generating a clock signal which is synchronous with a reproduced signal from an optical disc on which information is recorded, wherein the clock signal generation device includes an A/D converting means for sampling a reproduced signal in response to a clock signal and for convert the sampled reproduced signal into a digital signal so as to generate a plurality of digital values sequentially in time; and a clock oscillating means for generating the clock signal,
the semiconductor integrated circuit comprising:
a first phase error calculating means for calculating a first phase error value indicating a phase error between the reproduced signal and the clock signal based on each of the plurality of digital values;
a first displacement distribution detecting means for detecting a distribution of displacements of the first phase error values; and
a loop filter means for generating a control signal controlling a frequency of the clock signal based on the first phase error values and a detection result of the distribution of displacements of the first phase error values;
wherein:
the loop filter means generates the control signal such that a deviation of the distribution of displacements of the first error values becomes smaller, and
the clock oscillating means generates a signal having a frequency corresponding to the control signal as the clock signal.

21. A data reproduction method for generating a clock signal which is synchronous with a reproduced signal from an optical disc on which information is recorded and for outputting reproduced data obtained by digitizing the reproduced signal in synchronization with the clock signal, the data reproduction method comprising the steps of:
(a) sampling the reproduced signal in response to the clock signal and converting the sampled reproduced signal into a digital value so as to generate a plurality of digital values in the order of time sequence;
(b) calculating a first phase error value indicating a phase error between the reproduced signal and the clock signal based on each of the plurality of digital values;
(c) detecting a distribution of displacements of the first phase error values;
(d) generating a control signal controlling a frequency of the clock signal based on the first phase error values and a detection result of the distribution of displacements of the first phase error values; and
(e) generating a signal having a frequency corresponding to the control signal as the clock signal,
wherein the step (d) includes the step of generating the control signal such that a deviation of the distribution of displacements of the first phase error values becomes smaller.
